(19) United States
(12) Patent Application Publication
(10) Pub. No.: US 2025/0338599 A1
(43) Pub. Date: Oct. 30, 2025

(54) SEMICONDUCTOR GATE STRUCTURE AND METHODS OF FORMING THE SAME

(71) Applicant: Taiwan Semiconductor Manufacturing Co., Ltd., Hsinchu (TW)

(72) Inventors: Tsung-Han Shen, Taoyuan City (TW); Sheng-Yung Chang, Hsinchu (TW); Juan Peng Wong, Hsinchu (TW); Chieh Lin, Taichung City (TW); Chung-Yi Su, Taipei City (TW); Kuan-Ting Liu, Hsinchu (TW); Cheng-Lung Hung, Hsinchu (TW); Weng Chang, Hsinchu (TW); Chi On Chui, Hsinchu (TW)

(21) Appl. No.: 18/745,093

(22) Filed: Jun. 17, 2024

Related U.S. Application Data
(60) Provisional application No. 63/638,492, filed on Apr. 25, 2024.

(51) Int. Cl. H01L 21/8238; H01L 21/28; H01L 27/092; H01L 29/06; H01L 29/423; H01L 29/49; H01L 29/66; H01L 29/775; H01L 29/786

(52) U.S. Cl. CPC H10D 84/038; H01L 21/28088; H10D 30/014; H10D 30/031; H10D 30/43; H10D 30/6735; H10D 30/6739; H10D 30/6757; H10D 62/121; H10D 64/017; H10D 84/0177; H10D 84/85

(57) ABSTRACT

A method includes depositing a gate dielectric layer on a first channel region; depositing a p-type work function tuning layer on the gate dielectric layer; exposing the p-type work function tuning layer to a silicon-based precursor for a duration of time; and depositing a n-type work function tuning layer on the p-type work function tuning layer. Exposing the p-type work function tuning layer to the silicon-based precursor can form a silicon-containing layer on the p-type work function tuning layer.

### PRIORITY CLAIM AND CROSS-REFERENCE

This application claims the benefit of U.S. Provisional Application No. 63/638,492, filed on Apr. 25, 2024, which application is hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nanostructure-FET) in a three-dimensional view, in accordance with some embodiments.

FIGS. 2, 3, 4, 5, 6, 7, 8A, 8B, 8C, 9A, 9B, 9C, 10, 11A, 11B, 11C, 12A, 12B, 12C, 13A, 13B, 13C, 14A, 14B, 14C, 15A, 15B, 15C, 16A, 16B, 16C, 17A, 17B, 17C, 18A, 18B, and 18C are views of intermediate stages in the manufacturing of nanostructure-FETs, in accordance with some embodiments.

FIGS. 19A, 19B, and 19C are schematic illustrations of intermediate stages in a silicon soak process, in accordance with some embodiments.

FIGS. 20A, 20B, 20C, 21A, 21B, 21C, 22A, 22B, 22C, 23A, 23B, and 23C are views of intermediate stages in the manufacturing of nanostructure-FETs, in accordance with some embodiments.

FIGS. 24A, 24B, and 24C are schematic illustrations of intermediate stages in formation of an n-type work function tuning layer, in accordance with some embodiments.

FIG. 25 illustrates a graph of the growth of an n-type work function tuning layer, in accordance with some embodiments.

FIGS. 26A, 26B, 26C, 27A, 27B, 27C, 28A, 28B, and 28C are views of intermediate stages in the manufacturing of nanostructure-FETs, in accordance with some embodiments.

FIGS. 29, 30, 31, 32, and 33 are views of intermediate stages in the manufacturing of nanostructure-FETs, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, a silicon soak process is performed on a p-type work function tuning layer. The silicon soak process modifies the surface properties of the p-type work function tuning layer such that less n-type work function tuning material is formed on the p-type work function tuning layer. Reducing the amount of n-type work function tuning material formed on the p-type work function tuning layer in this manner can reduce the amount of n-type work function tuning material that diffuses into the underlying p-type work function tuning layer. This can reduce undesirable performance issues in p-type devices due to the diffusion of n-type work function tuning material, such as aluminum atoms, into the p-type work function tuning layer.

Embodiments are described below in a particular context, a die comprising nanostructure field-effect transistors (e.g., “nanostructure-FETs” or “nano-FETs”). Various embodiments may be applied, however, to dies comprising other types of transistors (e.g., fin field-effect transistors (FinFETs), planar transistors, or the like) in lieu of or in combination with the nanostructure-FETs.

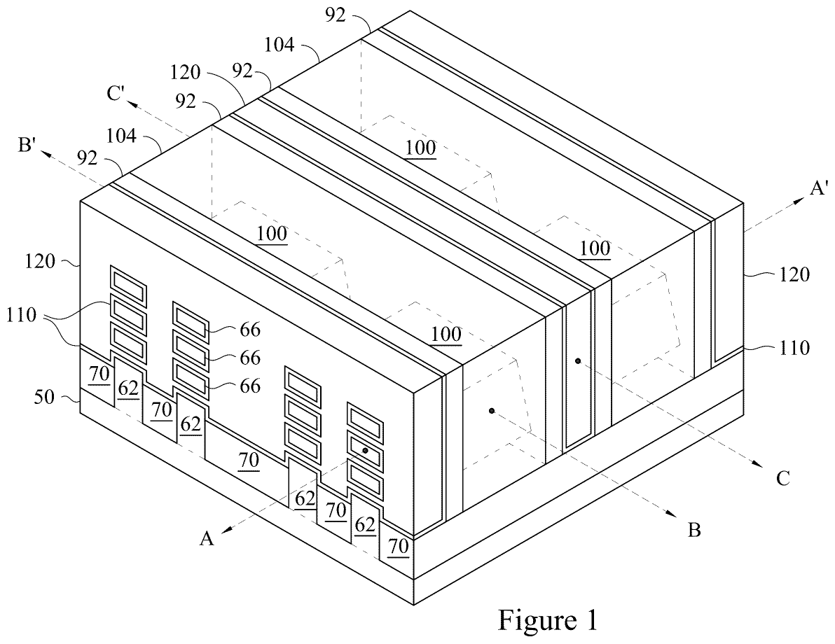

FIG. 1 illustrates an example of nanostructure-FETs (e.g., nanowire FETs, nanosheet FETs), gate-all-around (GAA) FETs, or the like) in a three-dimensional view, in accordance with some embodiments. Some features of the nanostructure-FETs may be omitted from FIG. 1 for clarity. The nanostructure-FETs include nanostructures 66 (e.g., nanosheets, nanowires, or the like) over fins 62 on a substrate 50 (e.g., a semiconductor substrate), with the nanostructures 66 being semiconductor features that act as channel regions for the nanostructure-FETs. Isolation regions 70, such as shallow trench isolation (STI) regions, are disposed between adjacent fins 62, which may protrude above and from between neighboring isolation regions 70. The nanostructures 66 are disposed over and between adjacent isolation regions 70. Although the isolation regions 70 are described/illustrated as being separate from the substrate 50, as used herein, the term “substrate” may refer to the semiconductor substrate alone or a combination of the semiconductor substrate and the isolation regions. Additionally, although a bottom portion of the fins 62 are illustrated as being single, continuous materials with the substrate 50, the bottom portion of the fins 62 and/or the substrate 50 may comprise a single material or a plurality of materials. In this context, the fins 62 refer to the portion extending between the neighboring isolation regions 70.

Gate dielectrics 110 are over top surfaces of the fins 62 and along top surfaces, sidewalls, and bottom surfaces of the nanostructures 66. Gate electrodes 120 are over the gate dielectrics 110. The gate electrodes 120 may include one or more work function layers (not separately illustrated in FIG. 1) over the gate dielectrics 110 and a fill material over the work function layer(s). Source/drain regions 100 are disposed on the fins 62 at opposing sides of the gate dielectrics 110 and the gate electrodes 120. Source/drain region(s) 100 may refer to a source or a drain, individually or collectively dependent upon the context. An inter-layer dielectric (ILD) 104 is formed over the source/drain regions 100. Contacts (subsequently described) to the source/drain regions 100 will be formed through the ILD 104. The source/drain regions 100 may be shared between various nanostructures 66. For example, adjacent source/drain regions 100 may be electrically connected, such as through coalescing or merging the source/drain regions 100 by epitaxial growth, or through coupling the source/drain regions 100 with a same contact.

FIG. 1 further illustrates reference cross-sections that are used in later figures. Cross-section A-A′ is along a longitudinal axis of a fin 62 of a nanostructure-FET and in a direction of, for example, a current flow between the source/drain regions 100 of the nanostructure-FET. Cross-section B-B′ is perpendicular to cross-section A-A′ and extends through source/drain regions 100 of the nanostructure-FETs. Cross-section C-C′ is parallel to cross-section B-B′ and along a longitudinal axis of a gate electrode 120. Subsequent figures refer to these reference cross-sections for clarity.

Some embodiments discussed herein are discussed in the context of nanostructure-FETs formed using a gate-last process. In other embodiments, a gate-first process may be used. Also, some embodiments contemplate aspects used in planar devices, such as planar FETs, or in fin field-effect transistors (FinFETs), in lieu of or in combination with the nanostructure-FETs. For example, FinFETs may include semiconductor fins on a substrate, with the semiconductor fins being semiconductor features which act as channel regions for the FinFETs. Similarly, planar FETs may include a substrate, with planar portions of the substrate being semiconductor features which act as channel regions for the planar FETs.

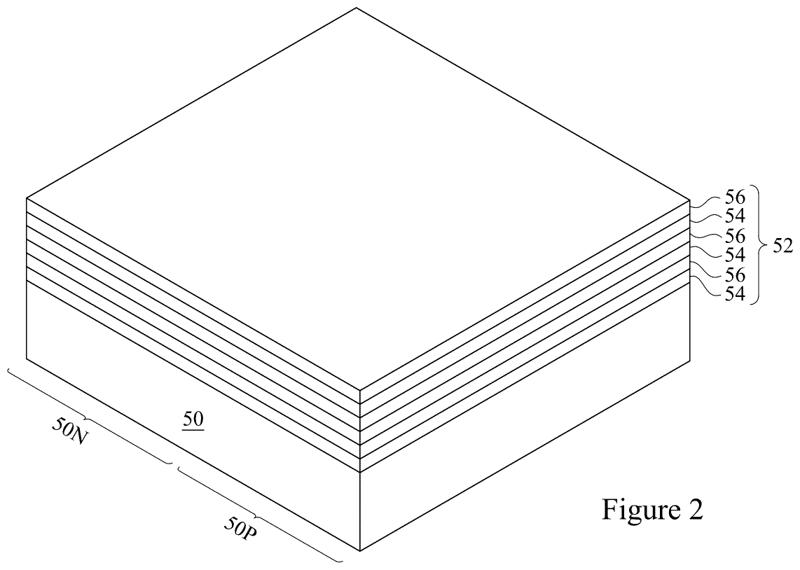

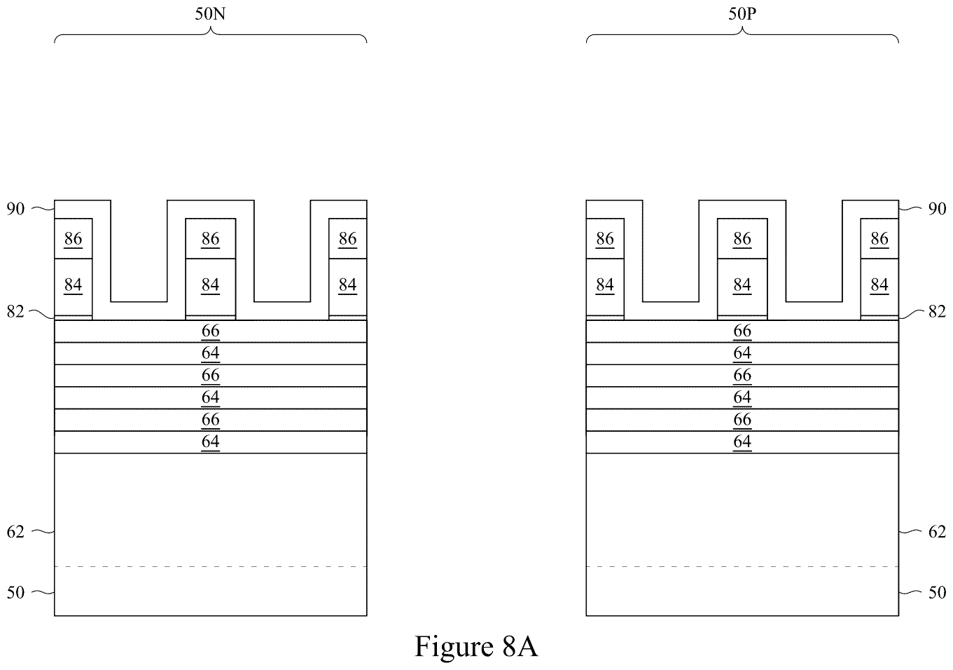

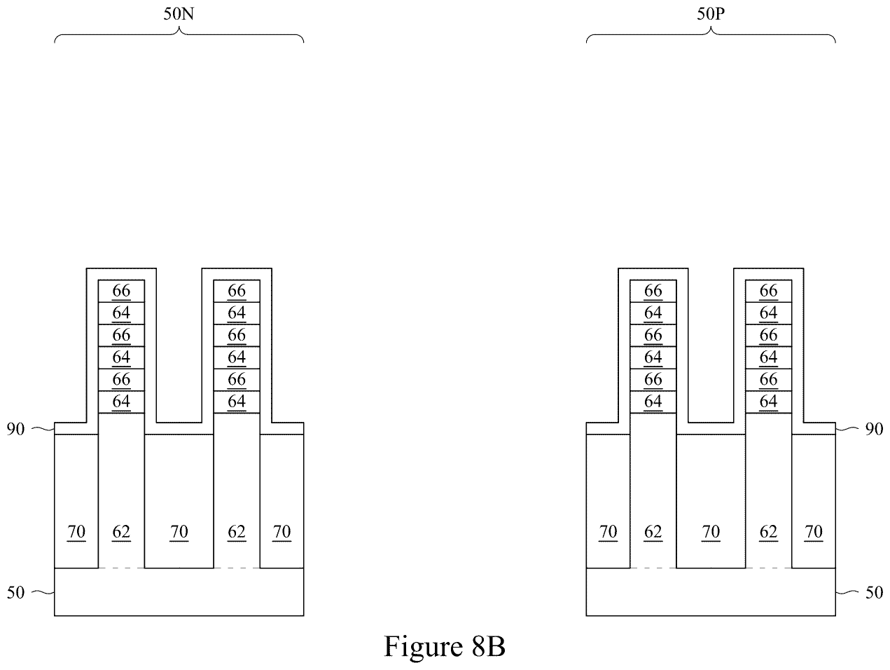

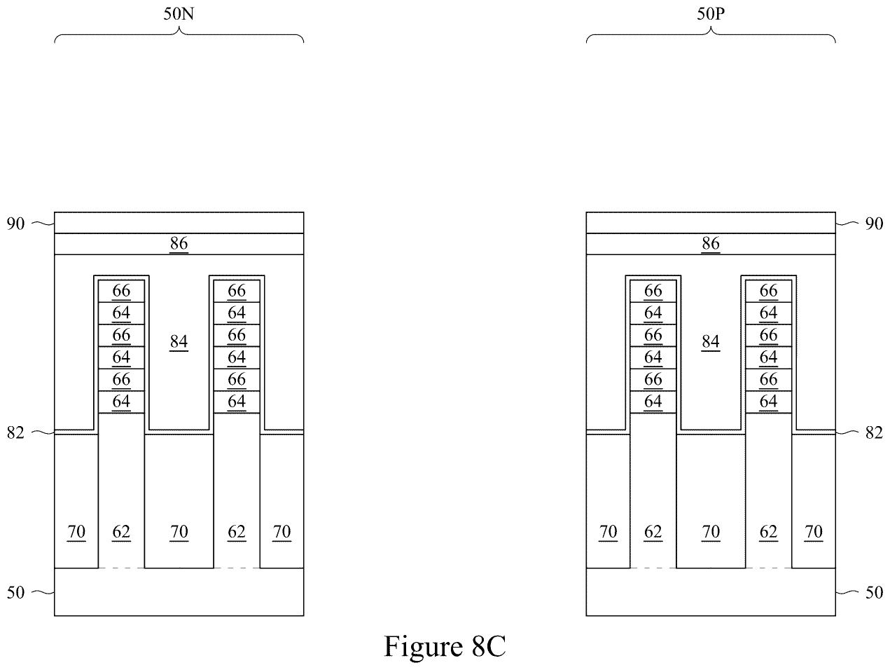

FIGS. 2-28C are views of intermediate stages in the manufacturing of nanostructure-FETs, in accordance with some embodiments. FIGS. 2, 3, 4, 5, 6, and 7 are three-dimensional views showing a similar three-dimensional view as FIG. 1. FIGS. 8A, 9A, 10, 11A, 12A, 13A, 14A, 15A, 16A, 17A, 18A, 20A, 21A, 22A, 23A, 26A, 27A, and 28A illustrate cross-sectional views along a similar cross-section as reference cross-section A-A′ in FIG. 1. FIGS. 8B, 9B, 11B, 12B, 13B, 14B, 15B, 16B, 17B, 18B, 20B, 21B, 22B, 23B, 26B, 27B, and 28B illustrate cross-sectional views along a similar cross-section as reference cross-section B-B′ in FIG. 1. FIGS. 8C, 9C, 11C, 12C, 13C, 14C, 15C, 16C, 17C, 18C, 20C, 21C, 22C, 23C, 26C, 27C, and 28C illustrate cross-sectional views along a similar cross-section as reference cross-section C-C′ in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nanostructure-FETs, and the p-type region 50P can be for forming p-type devices, such as PMOS transistors, e.g., p-type nanostructure-FETs. The n-type region 50N may (or may not) be physically separated (not separately illustrated) from the p-type region 50P, and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided.

Further in FIG. 2, a multi-layer stack 52 is formed over the substrate 50. The multi-layer stack 52 includes alternating first semiconductor layers 54 and second semiconductor layers 56. The first semiconductor layers 54 are formed of a first semiconductor material, and the second semiconductor layers 56 are formed of a second semiconductor material. The semiconductor materials may each be selected from the candidate semiconductor materials of the substrate 50.

In the illustrated embodiment, and as subsequently described in greater detail, the first semiconductor layers 54 will be removed and the second semiconductor layers 56 will patterned to form channel regions for the nanostructure-FETs in both the n-type region 50N and the p-type region 50P. In such embodiments, the channel regions in both the n-type region 50N and the p-type region 50P may have a same material composition (e.g., silicon or another semiconductor material) and be formed simultaneously. The first semiconductor layers 54 are dummy layers that will be removed in subsequent processing to expose top surfaces and bottom surfaces of the second semiconductor layers 56. The first semiconductor material of the first semiconductor layers 54 is a material that has a high etching selectivity from the etching of the second semiconductor layers 56, such as silicon germanium. The second semiconductor material of the second semiconductor layers 56 is a material suitable for both n-type and p-type devices, such as silicon.

In another embodiment (not separately illustrated), the first semiconductor layers 54 will be patterned to form channel regions for nanostructure-FETs in one region (e.g., the p-type region 50P), and the second semiconductor layers 56 will be patterned to form channel regions for nanostructure-FETs in another region (e.g., the n-type region 50N). The first semiconductor material of the first semiconductor layers 54 may be a material suitable for p-type devices, such as silicon germanium (e.g., SiₓGe₁₋ₓ, where x can be in the range of 0 to 1), pure germanium, a III-V compound semiconductor, a II-VI compound semiconductor, or the like. The second semiconductor material of the second semiconductor layers 56 may be a material suitable for n-type devices, such as silicon, silicon carbide, a III-V compound semiconductor, a II-VI compound semiconductor, or the like. The first semiconductor material and the second semiconductor material may have a high etching selectivity from the etching of one another, so that the first semiconductor layers 54 may be removed without significantly removing the second semiconductor layers 56 in the n-type region 50N, and the second semiconductor layers 56 may be removed without significantly removing the first semiconductor layers 54 in the p-type region 50P.

The multi-layer stack 52 is illustrated as including three of the first semiconductor layers 54 and three of the second semiconductor layers 56. It should be appreciated that the multi-layer stack 52 may include any number of the first semiconductor layers 54 and the second semiconductor layers 56. Each of the layers of the multi-layer stack 52 may be grown by a process such as vapor phase epitaxy (VPE) or molecular beam epitaxy (MBE), deposited by a process such as chemical vapor deposition (CVD) or atomic layer deposition (ALD), or the like. In some embodiments, some layers of the multi-layer stack 52 are formed to be thinner than other layers of the multi-layer stack 52.

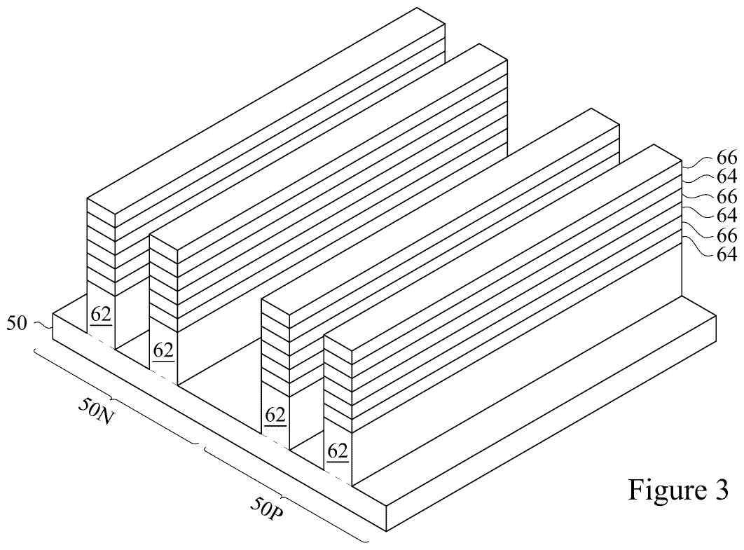

In FIG. 3, fins 62 are formed in the substrate 50, and nanostructures 64 and nanostructures 66 (collectively referred to as “nanostructures 64/66”) are formed in the multi-layer stack 52. In some embodiments, the nanostructures 64/66 and the fins 62 may be formed in the multi-layer stack 52 and the substrate 50, respectively, by etching trenches in the multi-layer stack 52 and the substrate 50. The etching may be any acceptable etch process, such as a reactive ion etch (RIE), neutral beam etch (NBE), the like, or a combination thereof. The etching may be anisotropic. Forming the nanostructures 64/66 by etching the multi-layer stack 52 may further define first nanostructures 64 from the first semiconductor layers 54 and define second nanostructures 66 from the second semiconductor layers 56.

The fins 62 and the nanostructures 64/66 may be patterned by any suitable method. For example, the fins 62 and the nanostructures 64/66 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 62 and the nanostructures 64/66.

The fins 62 are illustrated as having substantially equal widths in both the n-type region 50N and the p-type region 50P. In some embodiments, the widths of the fins 62 in the n-type region 50N may be greater or less than the width of the fins 62 in the p-type region 50P. Further, while each of the fins 62 and the nanostructures 64/66 are illustrated as having a constant width throughout, in other embodiments, the fins 62 and/or the nanostructures 64/66 may have tapered sidewalls such that a width of each of the fins 62 and/or the nanostructures 64/66 continuously increases in a direction towards the substrate 50. In such embodiments, each of the nanostructures 64/66 may have a different width and may be trapezoidal in shape.

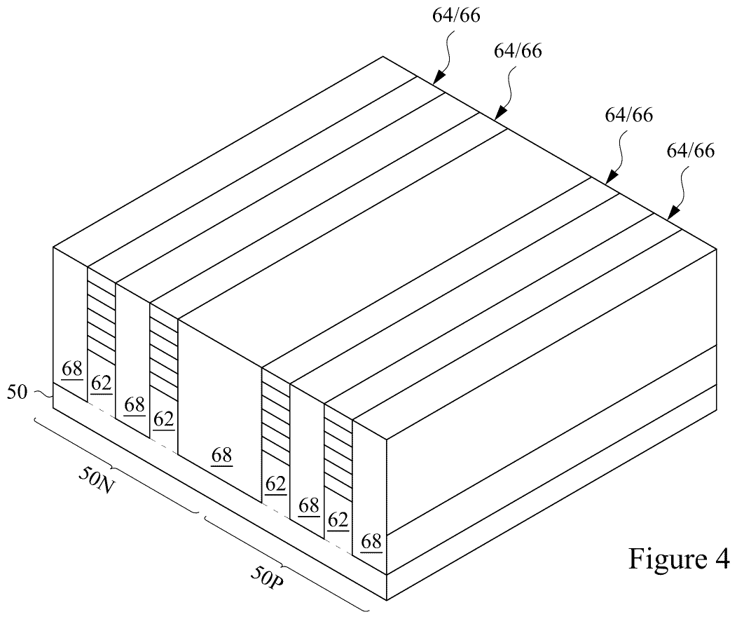

In FIG. 4, an insulation material 68 is formed over the substrate 50 and between adjacent fins 62 and adjacent nanostructures 64/66. The insulation material 68 may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In some embodiments, the insulation material 68 includes silicon oxide formed by an FCVD process. An annealing process may be performed once the insulation material 68 is formed. Although the insulation material 68 is illustrated as a single layer, some embodiments may utilize multiple layers. For example, in some embodiments a liner (not separately illustrated) may first be formed along a surface of the substrate 50, the fins 62, and the nanostructures 64/66. Thereafter, a fill material, such as one of the previously described insulation materials may be formed over the liner.

The insulation material 68 may be deposited over the fins 62 and nanostructures 64/66 such that excess insulation material 68 covers the nanostructures 64/66. A removal process is then applied to the insulation material 68 to remove excess insulation material 68 over the nanostructures 64/66. In some embodiments, a planarization process such as a chemical mechanical polish (CMP), an etch-back process, combinations thereof, or the like may be utilized. The planarization process exposes the nanostructures 64/66 such that top surfaces of the nanostructures 64/66 and the insulation material 68 are level after the planarization process is complete.

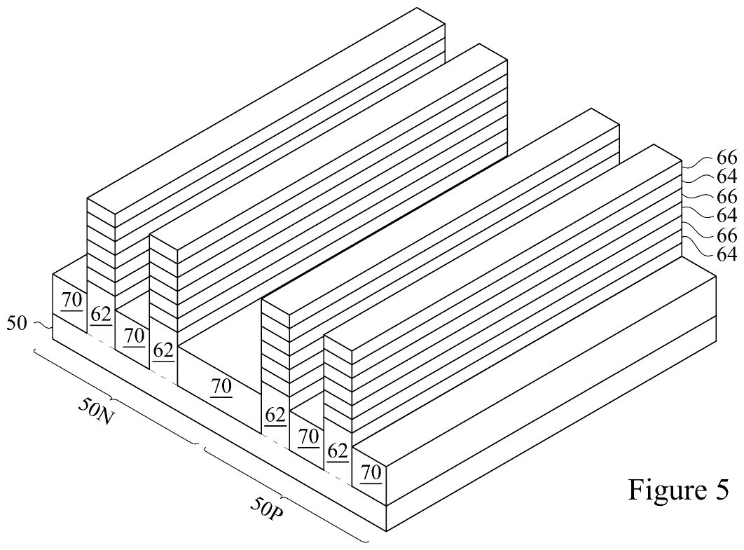

In FIG. 5, the insulation material 68 is recessed to form STI regions 70. The STI regions 70 are adjacent the fins 62. The insulation material 68 is recessed such that upper portions of fins 62 and/or the nanostructures 64/66 protrude from between neighboring STI regions 70. The upper portions of the fins 62 and/or the nanostructures 64/66 are above the STI regions 70. Further, the top surfaces of the STI regions 70 may have a flat surface as illustrated, a convex surface, a concave surface (such as dishing), or a combination thereof. The top surfaces of the STI regions 70 may be formed flat, convex, and/or concave by an appropriate etch. The STI regions 70 may be recessed using an acceptable etching process, such as one that is selective to the material of the insulation material 68 (e.g., etches the material of the insulation material 68 at a faster rate than the materials of the fins 62 and the nanostructures 64/66). For example, an oxide removal using, for example, dilute hydrofluoric (dHF) acid may be used.

The previously described process is just one example of how the fins 62 and the nanostructures 64/66 may be formed. In some embodiments, the fins 62 and/or the nanostructures 64/66 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 62 and/or the nanostructures 64/66. The epitaxial structures may comprise the previously described alternating semiconductor materials, such as the first semiconductor materials and the second semiconductor materials. In some embodiments in which epitaxial structures are epitaxially grown, the epitaxially grown materials may be in situ doped during growth, which may obviate prior and/or subsequent implantations, although in situ and implantation doping may be used together.

Further, appropriate wells (not separately illustrated) may be formed in the fins 62, the nanostructures 64/66, and/or the STI regions 70. In embodiments with different well types, different implant steps for the n-type region 50N and the p-type region 50P may be achieved using a photoresist or other mask (not separately illustrated). For example, a photoresist may be formed over the fins 62, the nanostructures 64/66, and the STI regions 70 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other mask (not separately illustrated) is formed over the fins 62, the nanostructures 64/66, and the STI regions 70 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

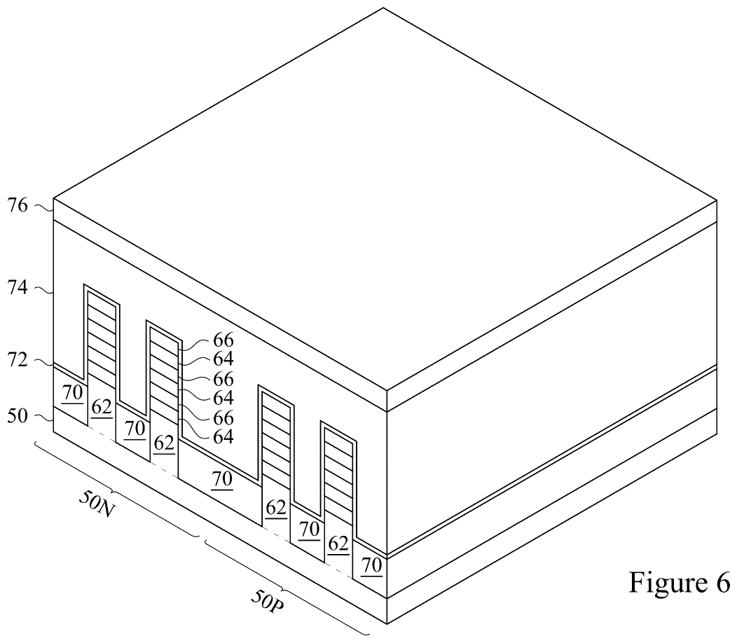

In FIG. 6, a dummy dielectric layer 72 is formed on the fins 62 and/or the nanostructures 64/66. The dummy dielectric layer 72 may be formed of silicon oxide, silicon nitride, a combination thereof, or the like, which may be deposited or thermally grown according to acceptable techniques. A dummy gate layer 74 is formed over the dummy dielectric layer 72, and a mask layer 76 is formed over the dummy gate layer 74. The dummy gate layer 74 may be deposited over the dummy dielectric layer 72 and then planarized, such as by a CMP process or the like. The dummy gate layer 74 may be formed of a conductive or non-conductive material and may be selected from a group including amorphous silicon, polycrystalline-silicon (polysilicon), polycrystalline silicon-germanium (poly-SiGe), metallic nitrides, metallic silicides, metallic oxides, and metals. The material of the dummy gate layer 74 may be deposited by CVD, physical vapor deposition (PVD), sputter deposition, or other techniques for depositing the selected material. The dummy gate layer 74 may be formed of other materials that have a high etching selectivity from the etching of insulation materials, e.g., the STI regions 70 and/or the dummy dielectric layer 72. The mask layer 76 may be deposited over the dummy gate layer 74. The mask layer 76 may be formed of a dielectric material such as silicon nitride, silicon oxynitride, or the like. In this example, a single dummy gate layer 74 and a single mask layer 76 are formed across the n-type region 50N and the p-type region 50P. In the illustrated embodiment, the dummy dielectric layer 72 covers the STI regions 70, such that the dummy dielectric layer 72 extends between the dummy gate layer 74 and the STI regions 70. In another embodiment, the dummy dielectric layer 72 covers only the fins 62 and/or the nanostructures 64/66.

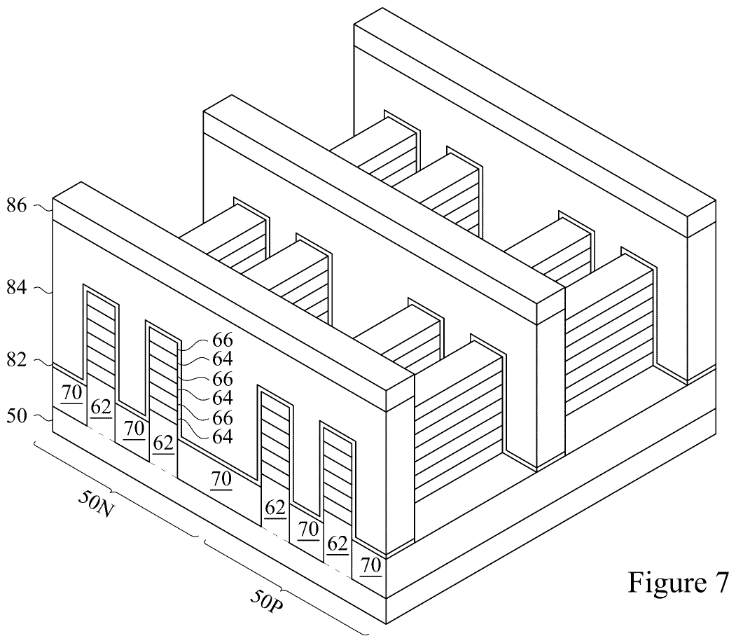

In FIG. 7, the mask layer 76 is patterned using acceptable photolithography and etching techniques to form masks 86. The pattern of the masks 86 then may be transferred to the dummy gate layer 74 and to the dummy dielectric layer 72 to form dummy gates 84 and dummy dielectrics 82, respectively. The dummy gates 84 cover respective channel regions of the nanostructures 64/66. The pattern of the masks 86 may be used to physically separate each of the dummy gates 84 from adjacent dummy gates 84. The dummy gates 84 may also have a lengthwise direction substantially perpendicular to the lengthwise direction of respective fins 62. The masks 86 can optionally be removed after patterning, such as by any acceptable etching technique.

In FIGS. 8A-8C, a spacer layer 90 is conformally formed over the nanostructures 64/66 and the STI regions 70, on exposed sidewalls of the masks 86 (if present), the dummy gates 84, the dummy dielectrics 82, the nanostructures 64/66, and the fins 62. The spacer layer 90 may be formed of one or more dielectric material(s). FIGS. 8A-8C show a spacer layer 90 formed of a single layer of dielectric material, but in other embodiments the spacer layer 90 may be formed of two or more layers of dielectric materials. Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other insulation materials formed by any acceptable process may be used. The spacer layer 90 is subsequently etched to form spacers.

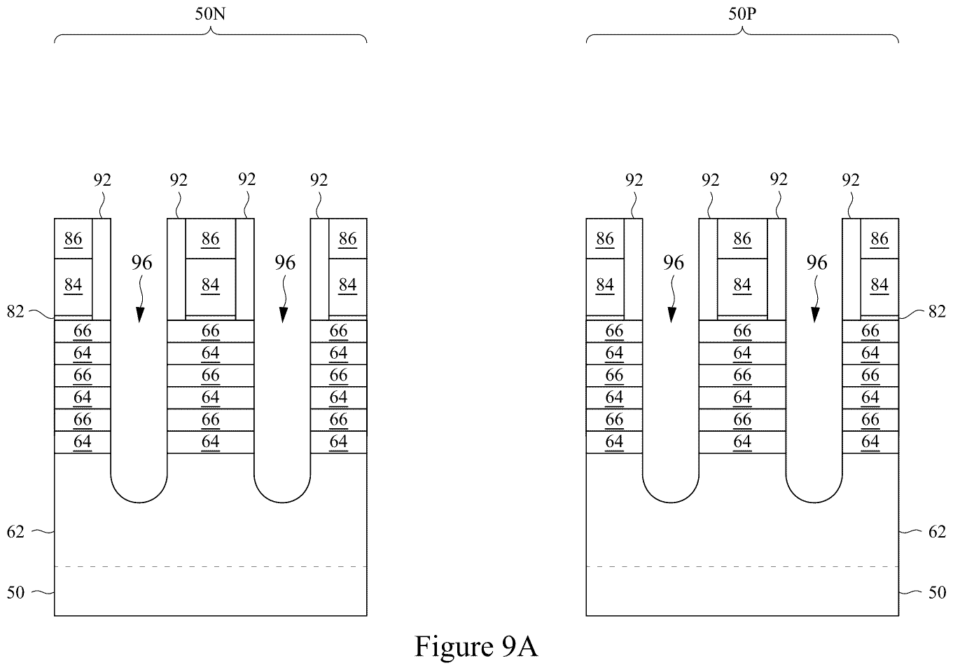

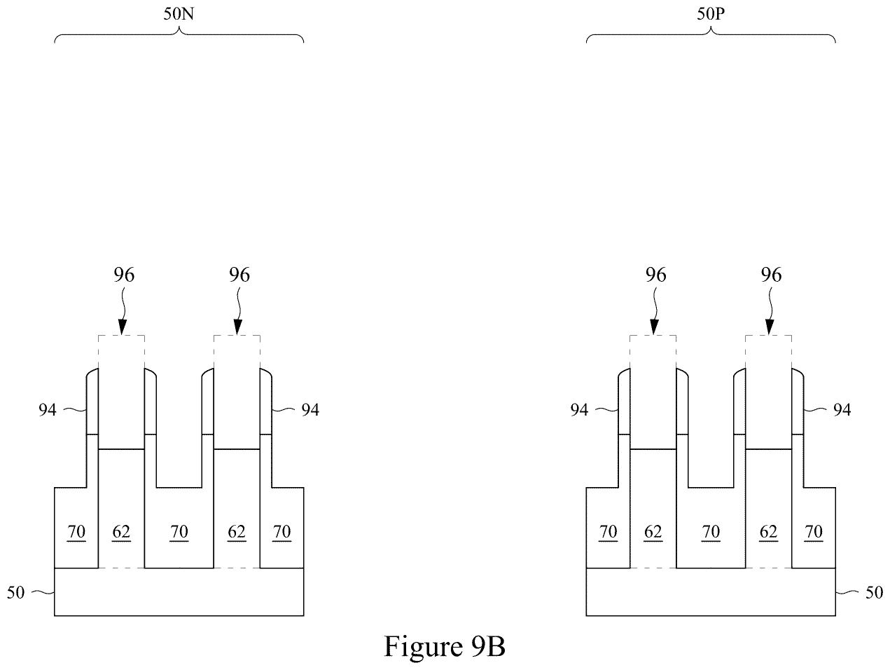

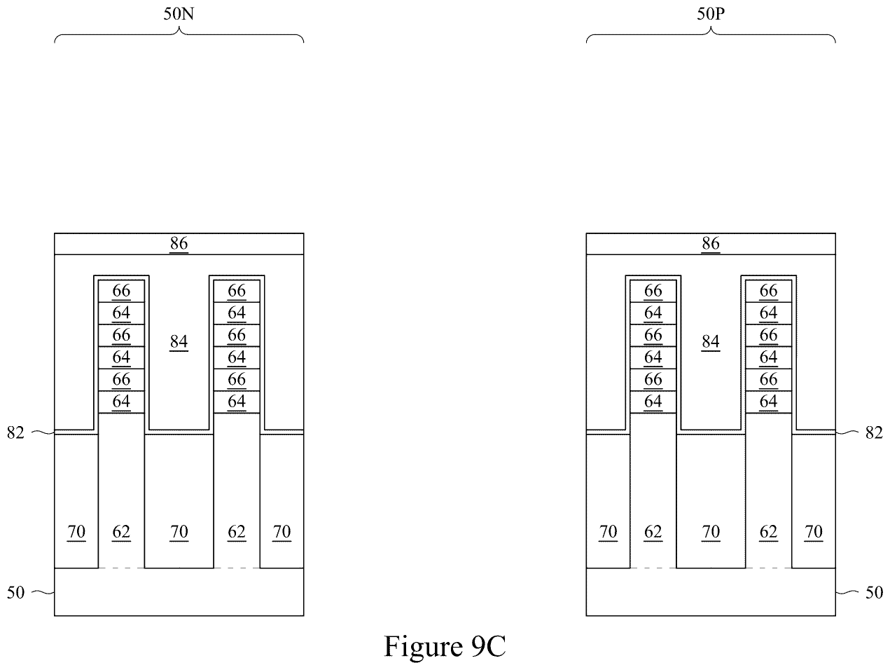

In FIGS. 9A-9C, the spacer layer 90 is patterned to form gate spacers 92 and fin spacers 94. Any acceptable etch process, such as a dry etch, a wet etch, the like, or a combination thereof, may be performed to pattern the spacer layer 90. The etching may be anisotropic. The spacer layer 90, when etched, has portions left on the sidewalls of the dummy gates 84 (thus forming the gate spacers 92) and has portions left on the sidewalls of the fins 62 and/or the nanostructures 64/66 (thus forming the fin spacers 94). After etching, the fin spacers 94 and/or the gate spacers 92 can have straight sidewalls or can have curved sidewalls. Additionally, the STI regions 70 may also be etched when patterning the spacer layer 90. The etching may recess portions of the STI regions 70 between the fins 62.

Further, implants for lightly doped source/drain (LDD) regions (not separately illustrated) may be performed. In embodiments with different device types, similar to the implants for the previously described wells, a mask, such as a photoresist, may be formed over the n-type region 50N, while exposing the p-type region 50P, and appropriate type (e.g., p-type) impurities may be implanted into the fins 62 and the nanostructures 64/66 exposed in the p-type region 50P. The mask may then be removed. Subsequently, a mask, such as a photoresist, may be formed over the p-type region 50P while exposing the n-type region 50N, and appropriate type impurities (e.g., n-type) may be implanted into the fins 62 and the nanostructures 64/66 exposed in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from about 10¹⁵ atoms/cm³ to about 10¹⁹ atoms/cm³. An anneal may be used to repair implant damage and to activate the implanted impurities.

It is noted that the previous disclosure generally describes a process of forming spacers and LDD regions. Other processes and sequences may be used. For example, fewer or additional spacers may be utilized, different sequence of steps may be utilized, additional spacers may be formed and removed, and/or the like. Furthermore, the n-type devices and the p-type devices may be formed using different structures and steps.

Still referring to FIGS. 9A-9C, source/drain recesses 96 are patterned in the fins 62, the nanostructures 64/66, and the substrate 50, in accordance with some embodiments. Epitaxial source/drain regions are subsequently formed in the source/drain recesses 96. The source/drain recesses 96 may extend through the nanostructures 64/66 and into the substrate 50. In some embodiments, the fins 62 may be etched such that bottom surfaces of the source/drain recesses 96 are disposed below the top surfaces of the STI regions 70. The source/drain recesses 96 may be formed by etching the fins 62, the nanostructures 64/66, and the substrate 50 using anisotropic etching processes, such as RIE, NBE, or the like. In some embodiments, the gate spacers 92 and the dummy gates 84 mask portions of the fins 62, the nanostructures 64/66, and the substrate 50 during the etching processes used to form the source/drain recesses 96. A single etch process or multiple etch processes may be used to etch each layer of the nanostructures 64/66 and/or the fins 62. Timed etch processes may be used to stop the etching of the source/drain recesses 96 after the source/drain recesses 96 reach a desired depth.

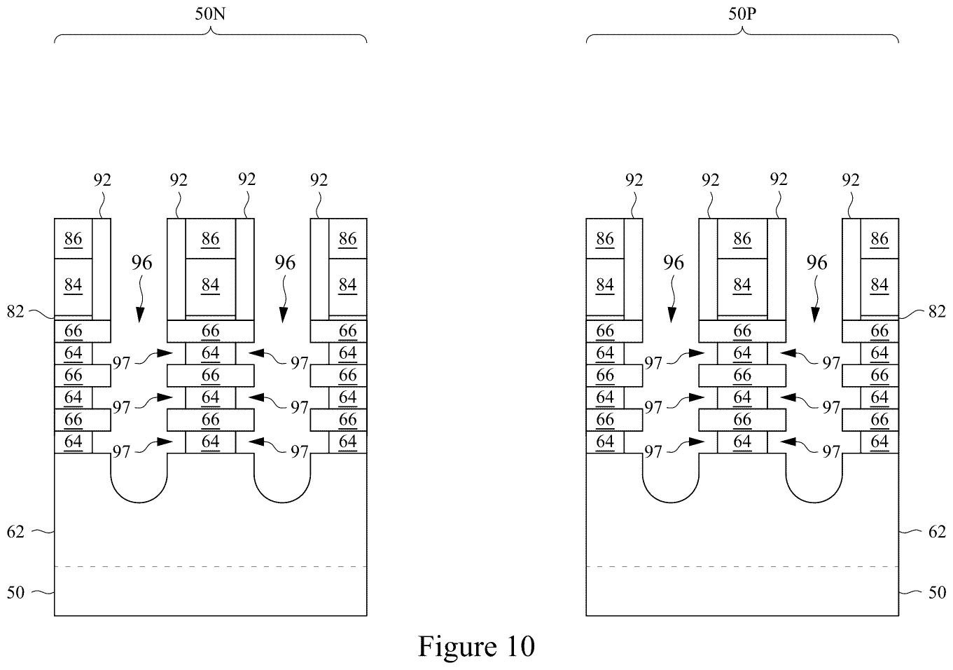

In FIG. 10, the source/drain recesses 96 are laterally expanded to form sidewall recesses 97 in the first nanostructures 64, in accordance with some embodiments. Specifically, portions of the sidewalls of the first nanostructures 64 exposed by the source/drain recesses 96 may be recessed to form sidewall recesses 97. Accordingly, a sidewall recess 97 may have a height that is about the same as a height (e.g., a thickness) of its corresponding first nanostructure 64. Although sidewalls of the first nanostructures 64 within the sidewall recesses 97 are illustrated as being flat, the sidewalls may be concave or convex. The sidewalls may be recessed by any acceptable etch process, such as one that is selective to the material of the first nanostructures 64 (e.g., selectively etches the material of the first nanostructures 64 at a faster rate than the material of the second nanostructures 66). The etching may be isotropic. For example, when the second nanostructures 66 are formed of silicon and the first nanostructures 64 are formed of silicon germanium, the etch process may be a wet etch using tetramethylammonium hydroxide (TMAH), ammonium hydroxide (NH₄OH), or the like. In another embodiment, the etch process may be a dry etch using a fluorine-based gas such as hydrogen fluoride (HF) gas. In some cases, the etch process may slightly recess (e.g., remove portions of) the second nanostructures 66 exposed by the sidewall recesses 97 as the sidewall recesses 97 are formed (not illustrated). In such cases, a sidewall recess 97 may have a height that is larger than the height (e.g., the thickness) of its corresponding first nanostructure 64. In some embodiments, the same etch process may be continually performed to both form the source/drain recesses 96 and recess the sidewalls of the first nanostructures 64 to form the sidewall recesses 97. In some cases, the sidewall recesses 97 may be considered part of the source/drain recesses 96.

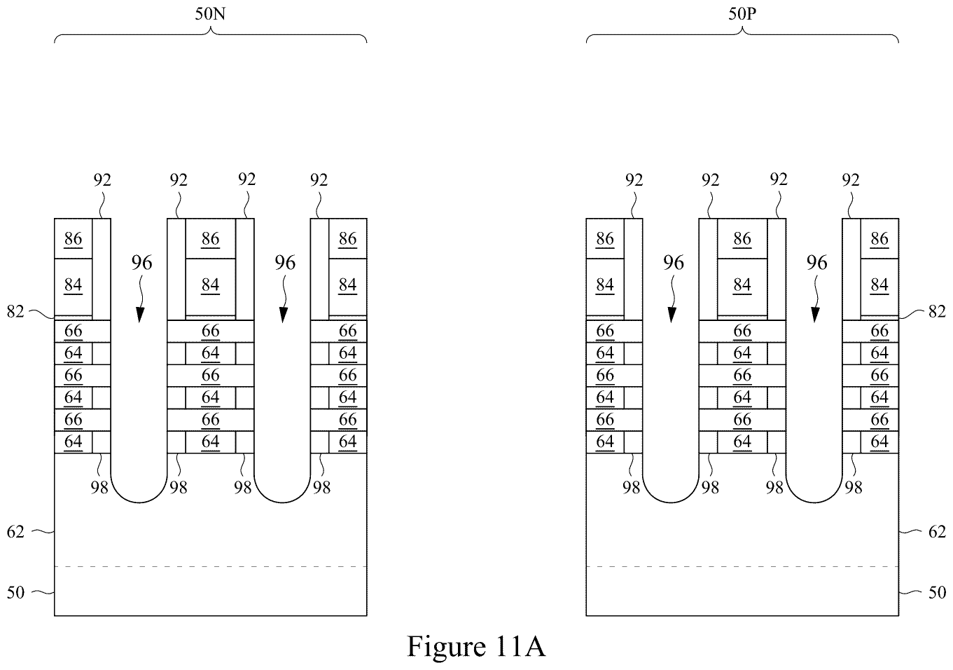

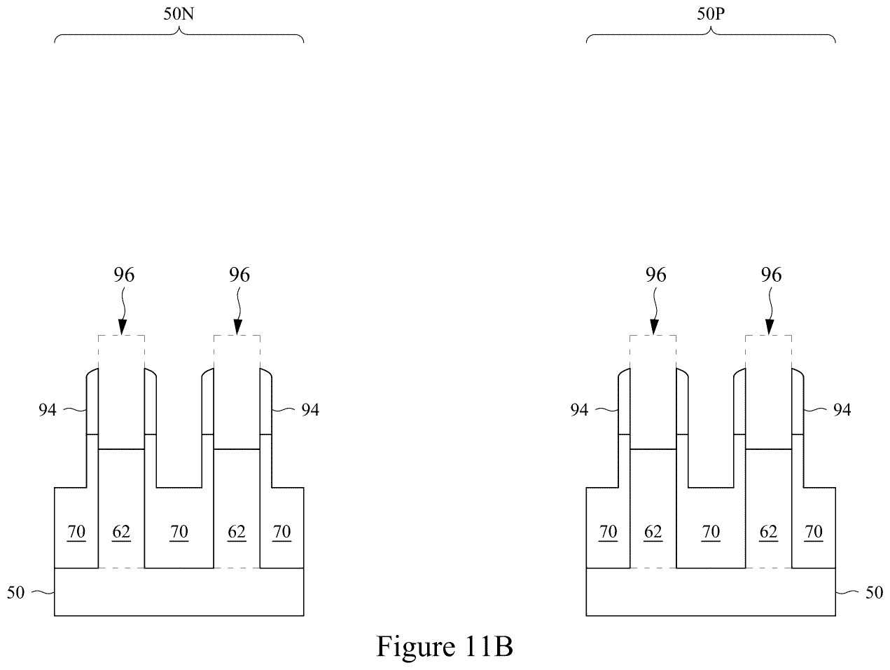

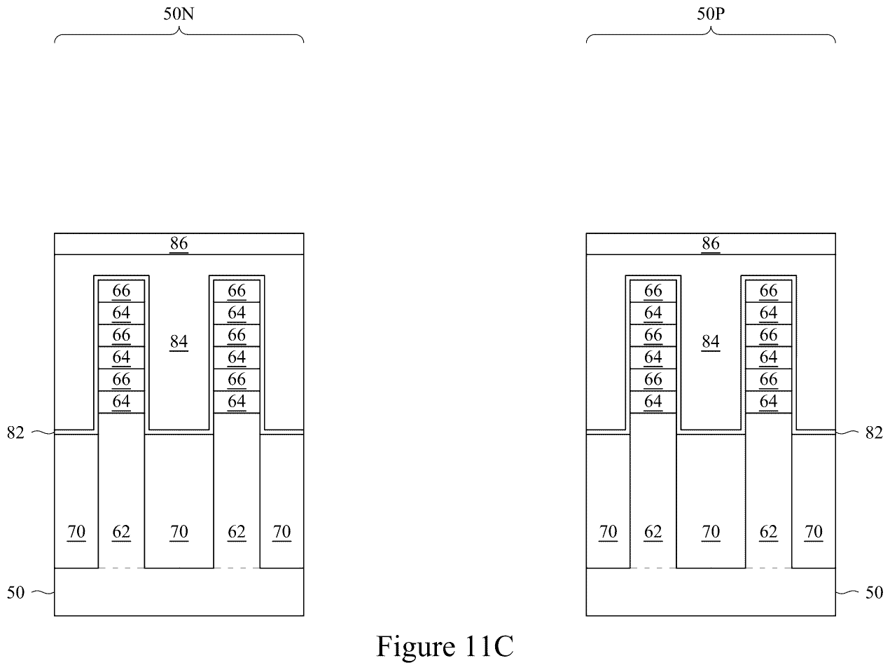

In FIGS. 11A-11C, inner spacers 98 are in the sidewall recesses 97, in accordance with some embodiments. In other words, the inner spacers 98 are formed on the sidewalls of the remaining portions of the first nanostructures 64. As will be subsequently described in greater detail, source/drain regions are subsequently formed in the source/drain recesses 96, and the first nanostructures 64 will be subsequently replaced with corresponding gate structures. The inner spacers 98 act as isolation features between the subsequently formed source/drain regions and the subsequently formed gate structures. Further, the inner spacers 98 may be used to prevent damage to the subsequently formed source/drain regions by subsequent etch processes, such as etch processes used to subsequently remove the first nanostructures 64.

In some embodiments, the inner spacers 98 are formed by conformally forming an insulating material in the source/drain recesses 96 and in the sidewall recesses 97, and subsequently etching the insulating material. The insulating material may be silicon nitride or silicon oxynitride, although any suitable material, such as low-dielectric constant (low-k) materials having a k-value less than about 3.5, may be utilized. The insulating material may be formed by a deposition process, such as ALD, CVD, or the like. The etching of the insulating material may be anisotropic. For example, the etch process may be a dry etch such as a RIE, a NBE, or the like. After performing the etching of the insulating material, the remaining portions of the insulating material within the sidewall recesses 97 form the inner spacers 98.

Although outer sidewalls of inner spacers 98 are illustrated as being flush (e.g. approximately coplanar) with sidewalls of the second nanostructures 66, the outer sidewalls of the inner spacers 98 may extend beyond or be recessed from sidewalls of the second nanostructures 66. In other words, the inner spacers 98 may partially fill, completely fill, or overfill the sidewall recesses 97. Moreover, although the sidewalls of the inner spacers 98 are illustrated as being flat, the sidewalls of the inner spacers 98 may be concave or convex. In some embodiments, an inner spacer 98 may have a thickness that is about the same as or greater than a thickness of an adjacent first nanostructure 64.

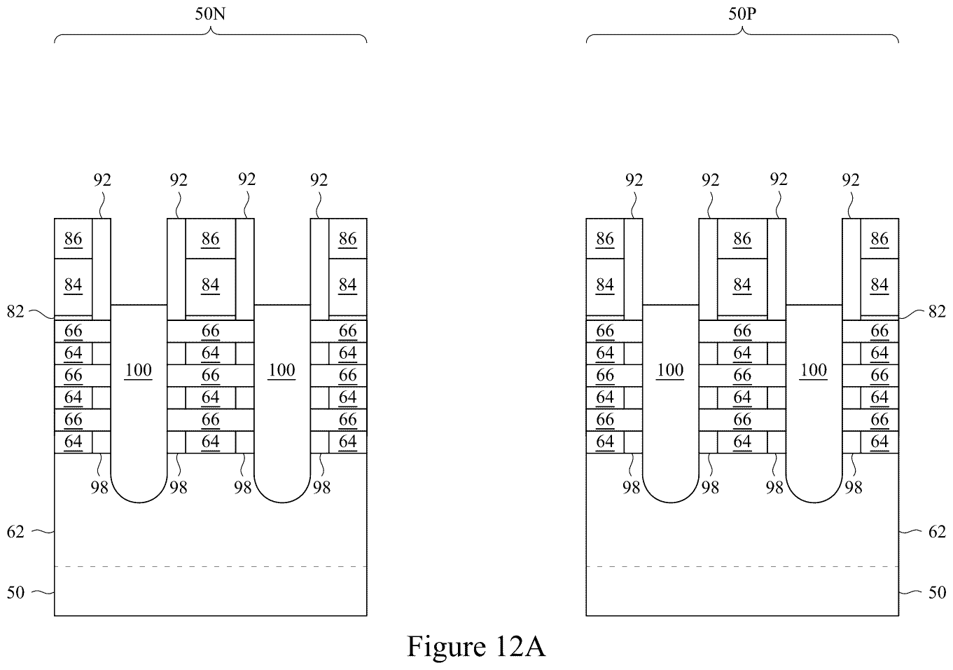

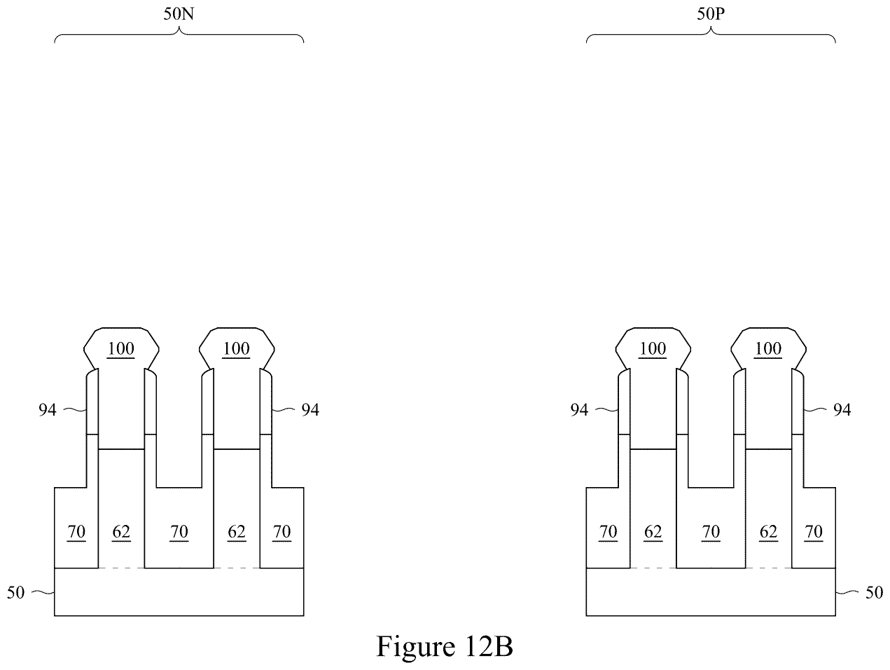

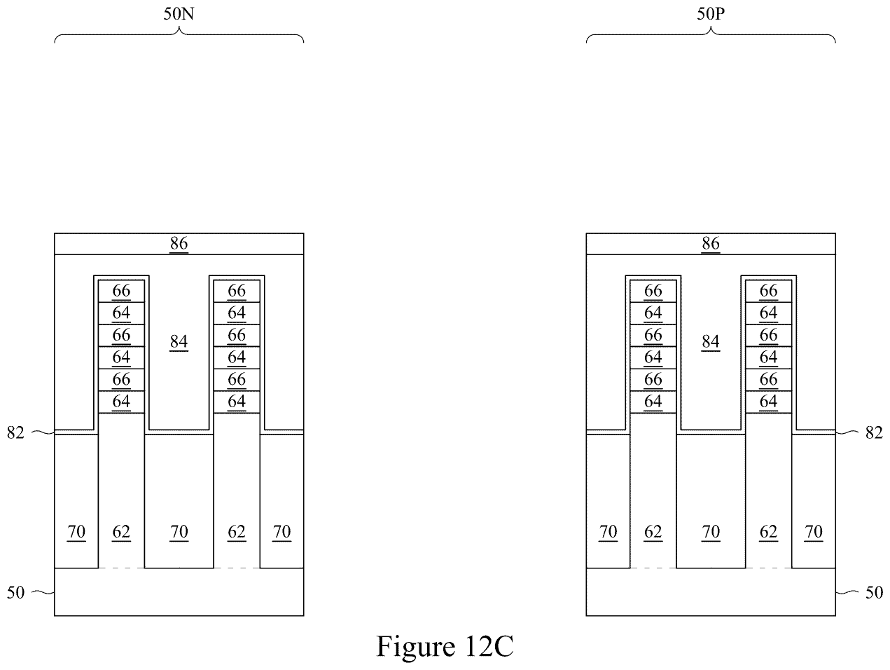

In FIGS. 12A-12C, epitaxial source/drain regions 100 are formed in the source/drain recesses 96 of the n-type region 50N and in the source/drain recesses 96 of the p-type region 50P, in accordance with some embodiments. The epitaxial source/drain regions 100 in the n-type region 50N may be referred to as “n-type source/drain regions,” and the epitaxial source/drain regions 100 in the p-type region 50P may be referred to as “p-type source/drain regions.” The n-type source/drain regions 100 may be formed before, after, or simultaneously with the formation of the p-type source/drain regions 100. In other embodiments, a semiconductor layer (not illustrated) may be formed in the source/drain recesses 96 before forming the epitaxial source/drain regions 100 in the source/drain recesses 96. The semiconductor layer may comprise, for example, undoped silicon or the like. In other embodiments, an insulating layer (not illustrated) may be deposited in the source/drain recesses before forming the epitaxial source/drain regions 100 in the source/drain recesses 96.

In some embodiments, the epitaxial source/drain regions 100 exert stress in the respective channel regions of the second nanostructures 66 within the p-type region 50P, thereby improving performance. The epitaxial source/drain regions 100 are formed in the source/drain recesses 96 such that each dummy gate 84 of the p-type region 50P is disposed between respective neighboring pairs of the epitaxial source/drain regions 100. In some embodiments, the gate spacers 92 are used to separate the epitaxial source/drain regions 100 from the dummy gates 84, and the inner spacers 98 are used to separate the epitaxial source/drain regions 100 from the nanostructures 64 by an appropriate lateral distance such that the epitaxial source/drain regions 100 do not short out with subsequently formed gates of the resulting p-type nanostructure-FETs.

The epitaxial source/drain regions 100 may also have surfaces raised from respective surfaces of the nanostructures 64/66 and may have facets. For example, as a result of the epitaxy processes used to form the epitaxial source/drain regions 100, upper surfaces of the epitaxial source/drain regions 100 can have facets which expand laterally outward beyond sidewalls of the nanostructures 64/66. In some embodiments, these facets cause adjacent epitaxial source/drain regions 100 of a same nanostructure-FET to merge. In other embodiments, adjacent epitaxial source/drain regions 100 remain separated after the epitaxy process is completed, as illustrated by FIG. 12B. In the illustrated embodiments, the fin spacers 94 are formed on top surfaces of the STI regions 70, thereby blocking the epitaxial growth. In some other embodiments, the fin spacers 94 may cover portions of the sidewalls of the nanostructures 64/66 and/or the fins 62, further blocking the epitaxial growth. In another embodiment, the spacer etch used to form the gate spacers 92 is controlled to not form the fin spacers 94, so as to allow the epitaxial source/drain regions 100 to extend to the surface of the STI region 70. In some embodiments, the epitaxial source/drain regions 100 extend above the top surface of the nanostructures 66. As a result, the top surface of an epitaxial source/drain region 100 may be disposed further from the substrate 50 than the top surface of the adjacent nanostructures 66.

The p-type source/drain regions 100 may be formed by an epitaxy process, such as such as vapor phase epitaxy (VPE), molecular beam epitaxy (MBE), or the like. The p-type source/drain regions 100 may include any acceptable material appropriate for p-type nanostructure-FETs. For example, if the second nanostructures 66 are formed of silicon, the p-type source/drain regions 100 may comprise materials exerting a compressive strain on the second nanostructures 66, such as silicon germanium, boron doped silicon germanium, germanium, germanium tin, or the like. The p-type source/drain regions 100 may be formed of a single layer of semiconductor material or may be formed of two or more sublayers of semiconductor materials. The epitaxial source/drain regions 100, the nanostructures 64/66, and/or the fins 62 within the p-type region 50P may be implanted with dopants, similar to the process previously discussed for forming lightly-doped source/drain regions, followed by an anneal. The p-type source/drain regions 100 may have an impurity concentration of between about 10¹⁹ atoms/cm³ to about 10²¹ atoms/cm³. Other concentrations are possible. In some embodiments, the p-type source/drain regions 100 may be in situ doped during growth.

The n-type source/drain regions 100 may be formed by an epitaxy process, such as such as VPE, MBE, or the like. The n-type source/drain regions 100 may include any acceptable material appropriate for n-type nanostructure-FETs. For example, if the second nanostructures 66 are formed of silicon, the n-type source/drain regions 100 may comprise materials exerting a tensile strain on the second nanostructures 66, such as silicon, silicon carbide, phosphorous doped silicon carbide, silicon phosphide (SiP), or the like. The n-type source/drain regions 100 may be formed of a single layer of semiconductor material or may be formed of two or more sublayers of semiconductor materials. The epitaxial source/drain regions 100, the nanostructures 64/66, and/or the fins 62 within the n-type region 50N may be implanted with dopants, similar to the process previously discussed for forming lightly-doped source/drain regions, followed by an anneal. The n-type source/drain regions 100 may have an impurity concentration of between about 10¹⁹ atoms/cm³ to about 10²¹ atoms/cm³. Other concentrations are possible. In some embodiments, the n-type source/drain regions 100 may be in situ doped during growth.

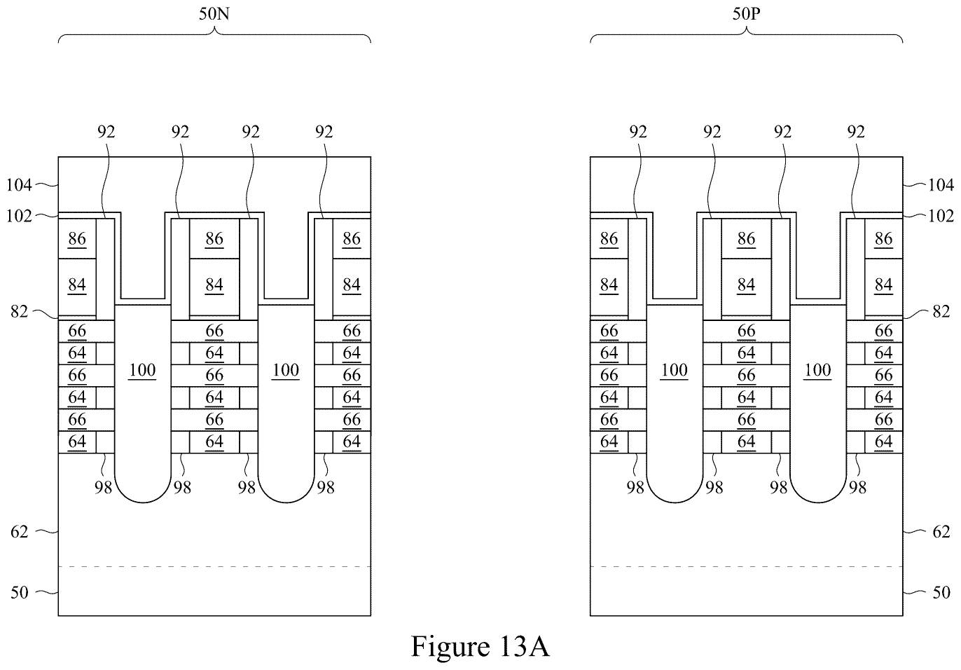

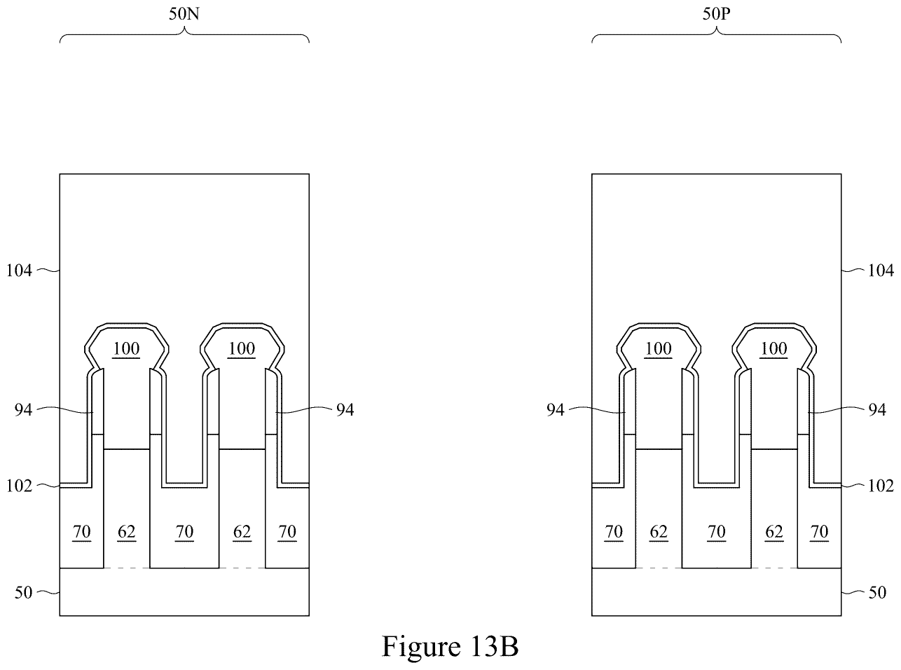

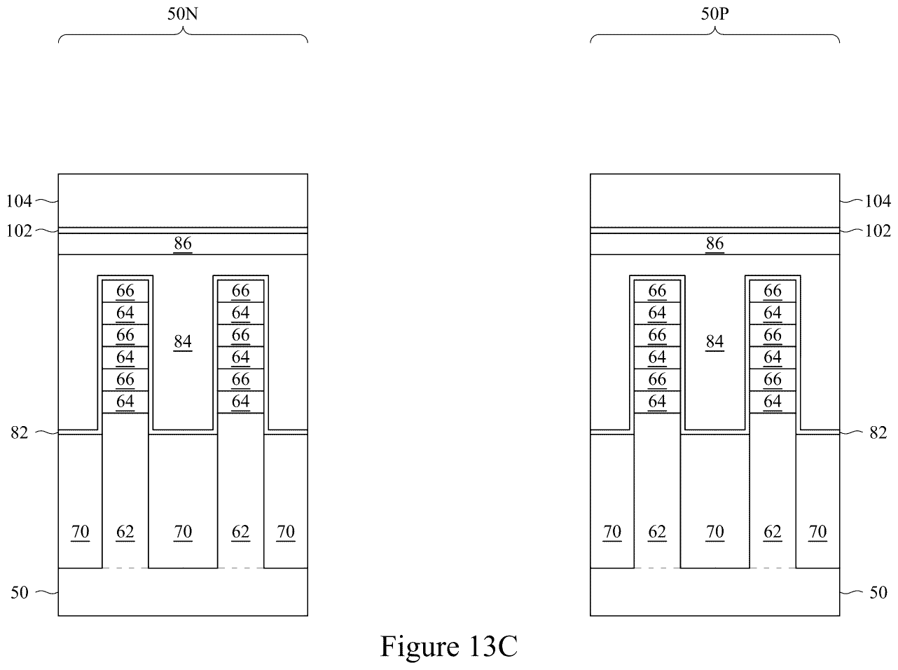

In FIGS. 13A-13C, a first ILD 104 is deposited over the epitaxial source/drain regions 100, the fin spacers 94, the gate spacers 92, the masks 86 (if present), and/or the dummy gates 84. The first ILD 104 may be formed of a dielectric material, which may be deposited by any suitable method, such as CVD, plasma-enhanced CVD (PECVD), or FCVD. Suitable dielectric materials may include silicon oxide, phospho-silicate glass (PSG), boro-silicate glass (BSG), boron-doped phospho-silicate glass (BPSG), undoped silicate glass (USG), or the like. Other insulation materials formed by any acceptable process may be used.

In some embodiments, a contact etch stop layer (CESL) 102 is formed between the first ILD 104 and the epitaxial source/drain regions 100, the fin spacers 94, the gate spacers 92, the masks 86 (if present), and/or the dummy gates 84. The CESL 102 may be formed of a dielectric material having a high etching selectivity from the etching of the first ILD 104, such as silicon nitride, silicon oxide, silicon oxynitride, a combination thereof, or the like, which may be formed using any suitable deposition process, such as CVD, ALD, or the like.

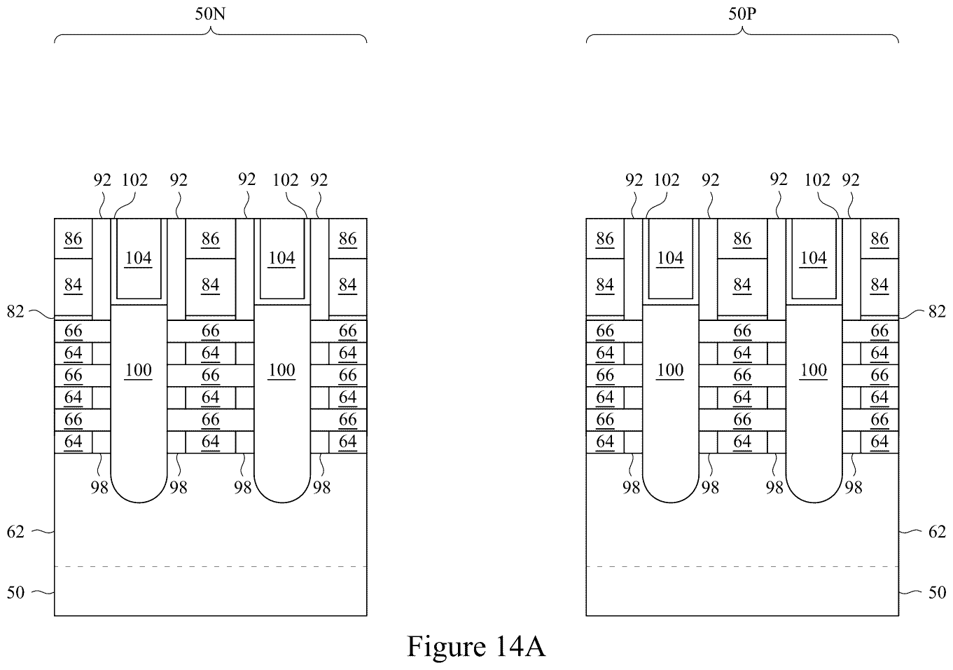

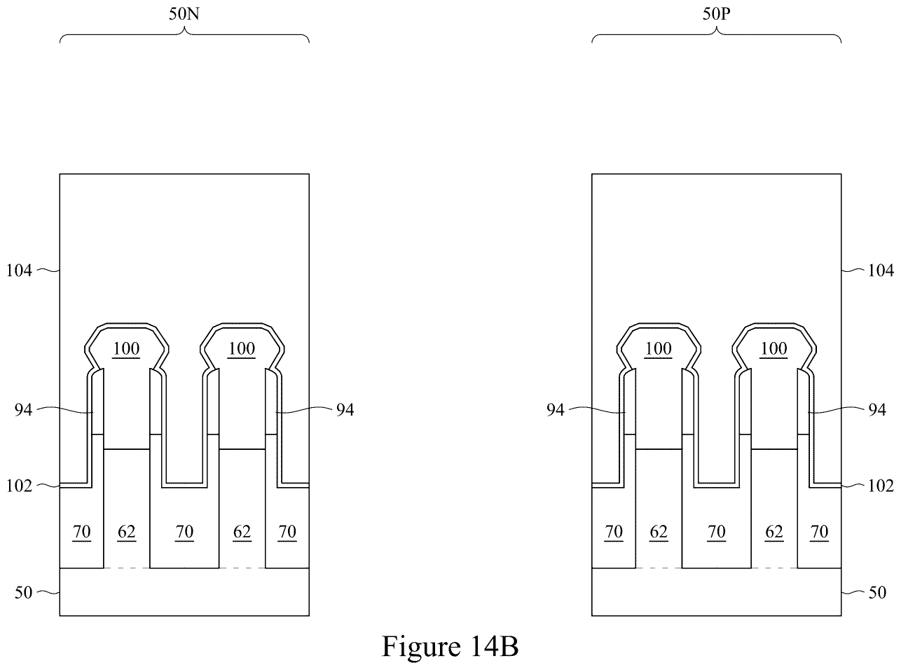

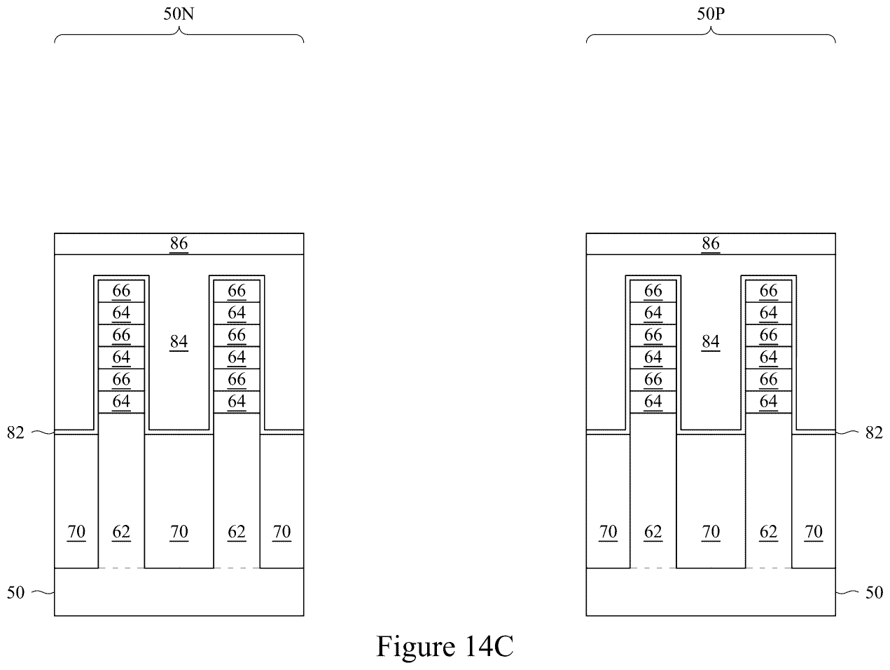

In FIGS. 14A-14C, a removal process is performed to level the top surfaces of the first ILD 104 with the top surfaces of the gate spacers 92 and the masks 86 (if present) or the dummy gates 84. In some embodiments, the removal process comprises a planarization process such as a chemical mechanical polish (CMP), a grinding process, an etch-back process, a combination thereof, or the like. The planarization process may also remove the masks 86 on the dummy gates 84, and portions of the gate spacers 92 along sidewalls of the masks 86. After the planarization process, top surfaces of the first ILD 104, the gate spacers 92, and the masks 86 (if present), and/or the dummy gates 84 are substantially level or coplanar (within process variations). Accordingly, the top surfaces of the masks 86 (if present) and/or the dummy gates 84 may be exposed through the first ILD 104.

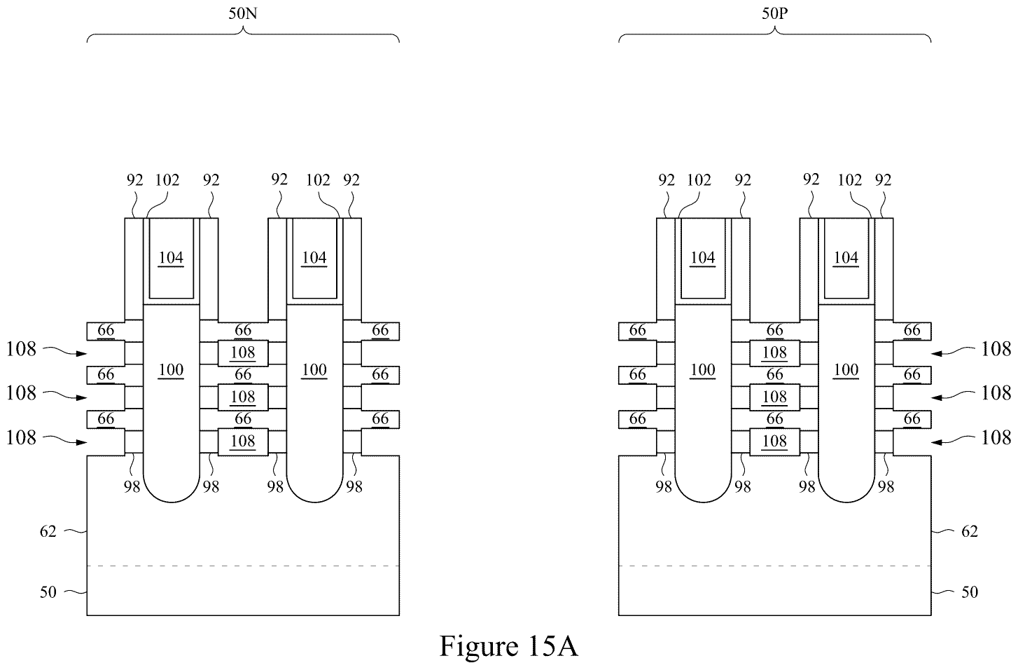

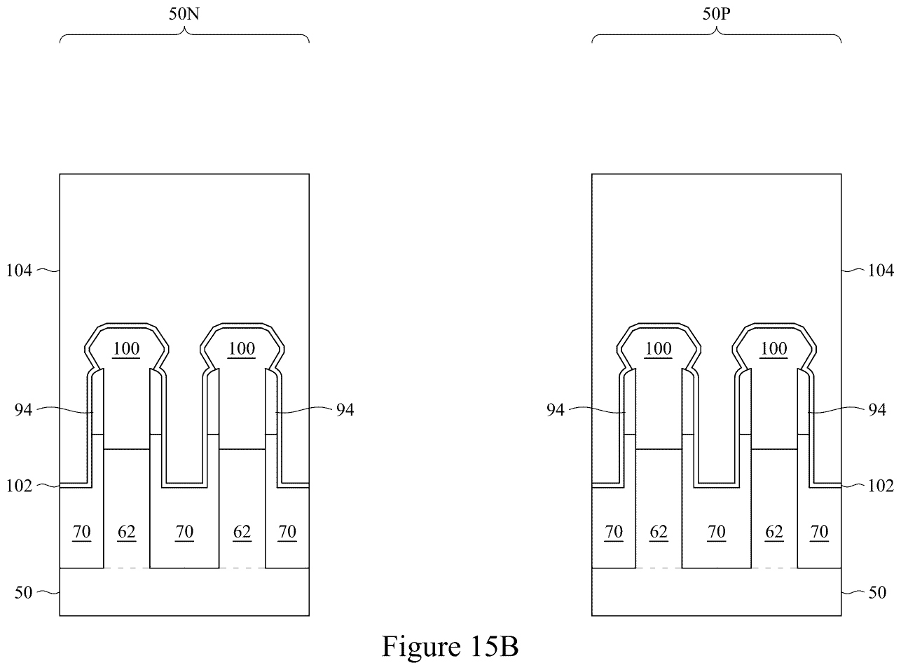

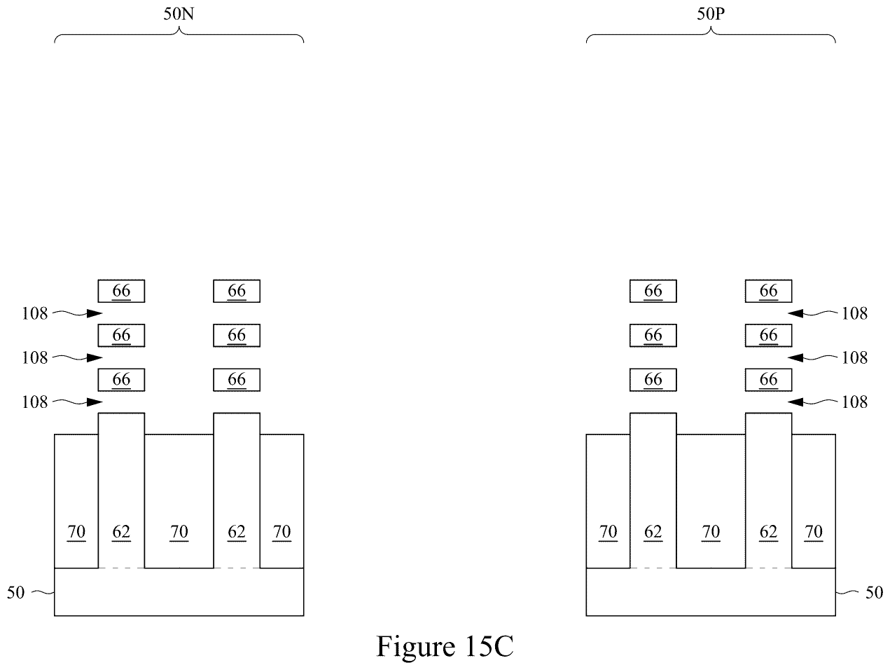

In FIGS. 15A-15C, the masks 86 (if present) and the dummy gates 84 are removed in one or more etching steps, such that recesses are formed between the gate spacers 92. In some embodiments, the dummy gates 84 and the dummy dielectrics 82 are removed by an anisotropic dry etch process. For example, the etching process may include a dry etch process using reaction gas(es) that selectively etch the material of the dummy gates 84 at a faster rate than the materials of the first ILD 104 and the gate spacers 92. Each recess exposes and/or overlies portions of nanostructures 64/66, which act as the channel regions in subsequently completed nanostructure-FETs. Portions of the nanostructures 64/66 which act as the channel regions are disposed between neighboring pairs of the epitaxial source/drain regions 100 in the n-type region 50N or between neighboring pairs of the epitaxial source/drain regions 100 in the p-type region 50P. During the removal, the dummy dielectrics 82 may be used as etch stop layers when the dummy gates 84 are etched. The dummy dielectrics 82 may then be removed after the removal of the dummy gates 84.

The remaining portions of the first nanostructures 64 are then removed to form openings 108 in regions between the second nanostructures 66. The remaining portions of the first nanostructures 64 can be removed by any acceptable etch process that selectively etches the material of the first nanostructures 64 at a faster rate than the material of the second nanostructures 66. The etching may be isotropic. For example, when the first nanostructures 64 are formed of silicon germanium and the second nanostructures 66 are formed of silicon, the etch process may be a wet etch using tetramethylammonium hydroxide (TMAH), ammonium hydroxide (NH₄OH), or the like. In some embodiments, a trim process (not separately illustrated) is performed to decrease the thicknesses of the exposed portions of the second nanostructures 66 and expand the openings 108. Hereinafter, the second nanostructures 66 may be referred to as nanostructures 66, and the nanostructures 66 over each fin 62 may be referred to as “stacks” of nanostructures 66.

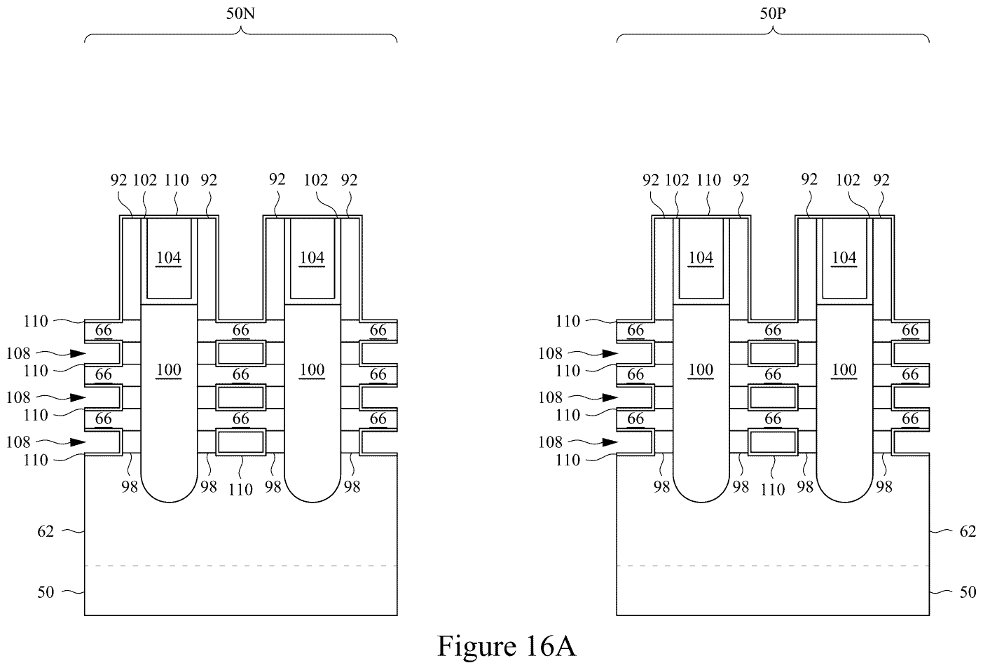

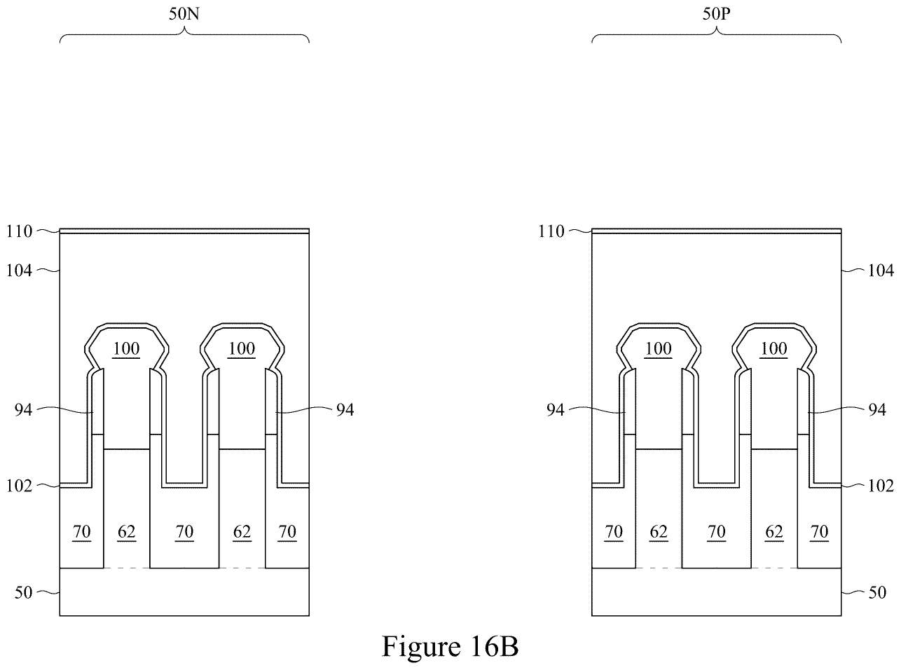

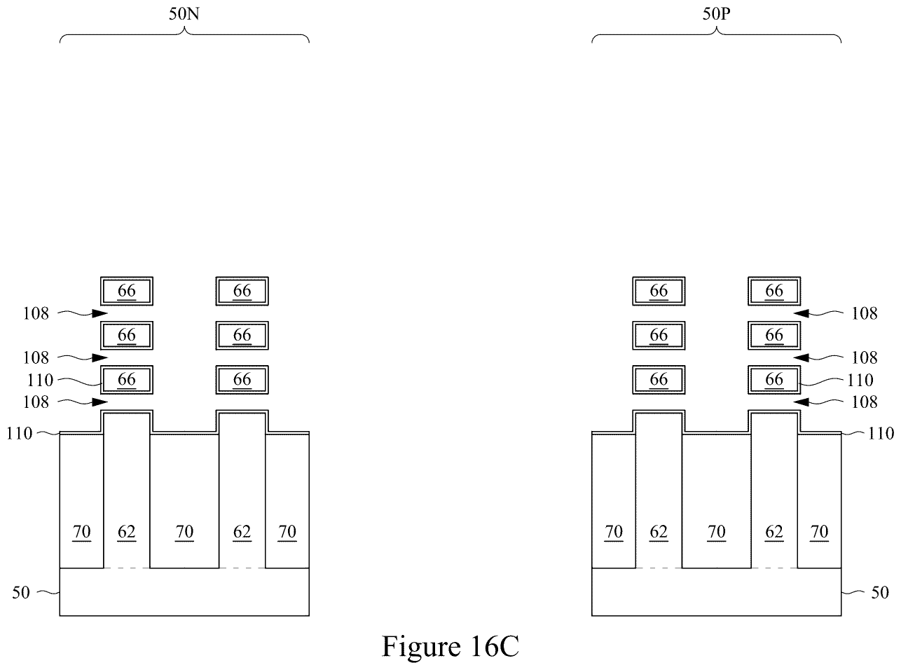

FIGS. 16A through 26C illustrate intermediate steps in the formation of replacement gates comprising gate dielectrics 110 and gate electrodes 120, in accordance with some embodiments. Each respective pair of a gate dielectric 110 and a gate electrode 120 may be collectively referred to as a “gate structure” or a “gate stack.” Each gate structure is wrapped around a channel region of a nanostructure 66, such that the gate structure extends along sidewalls, a bottom surface, and a top surface of the nanostructure 66. Some of the gate structures also extend along sidewalls and/or a top surface of a fin 62.

In FIGS. 16A-16C, gate dielectrics 110 are formed as part of the replacement gates, in accordance with some embodiments. The gate dielectrics 110 include one or more gate dielectric layer(s) disposed on the sidewalls and/or the top surfaces of the fins 62; on the top surfaces, the sidewalls, and the bottom surfaces of the channel regions of the nanostructures 66; on the sidewalls of the inner spacers 98 adjacent the source/drain regions 100; and on the sidewalls of the gate spacers 92. In other words, the gate dielectrics 110 may be conformally deposited within the openings 108. The gate dielectrics 110 may also be formed on top surfaces of the gate spacers 92, the first ILD 104, and/or the CESL 102. The gate dielectrics 110 may be formed of an oxide such as silicon oxide or a metal oxide, a silicate such as a metal silicate, combinations thereof, multi-layers thereof, or the like. Additionally or alternatively, the gate dielectrics 110 may be formed of a high-k dielectric material (e.g., dielectric materials having a k-value greater than about 7.0), such as a metal oxide or a silicate of hafnium, aluminum, zirconium, lanthanum, manganese, barium, titanium, lead, and combinations thereof. The dielectric material(s) of the gate dielectrics 110 may be formed by molecular-beam deposition (MBD), ALD, PECVD, or the like. Although single-layered gate dielectrics 110 are illustrated, the gate dielectrics 110 may include any number of interfacial layers and any number of main layers. For example, the gate dielectrics 110 may include an interfacial layer and an overlying high-k dielectric layer. The formation of the gate dielectrics 110 in the n-type region 50N and the p-type region 50P may occur simultaneously such that the gate dielectrics 110 in each region are formed of the same materials. In some embodiments, the gate dielectrics 110 in each region may be formed by distinct processes, such that the gate dielectrics 110 may be different materials and/or have a different number of layers. Various masking steps may be used to mask and expose appropriate regions when using distinct processes.

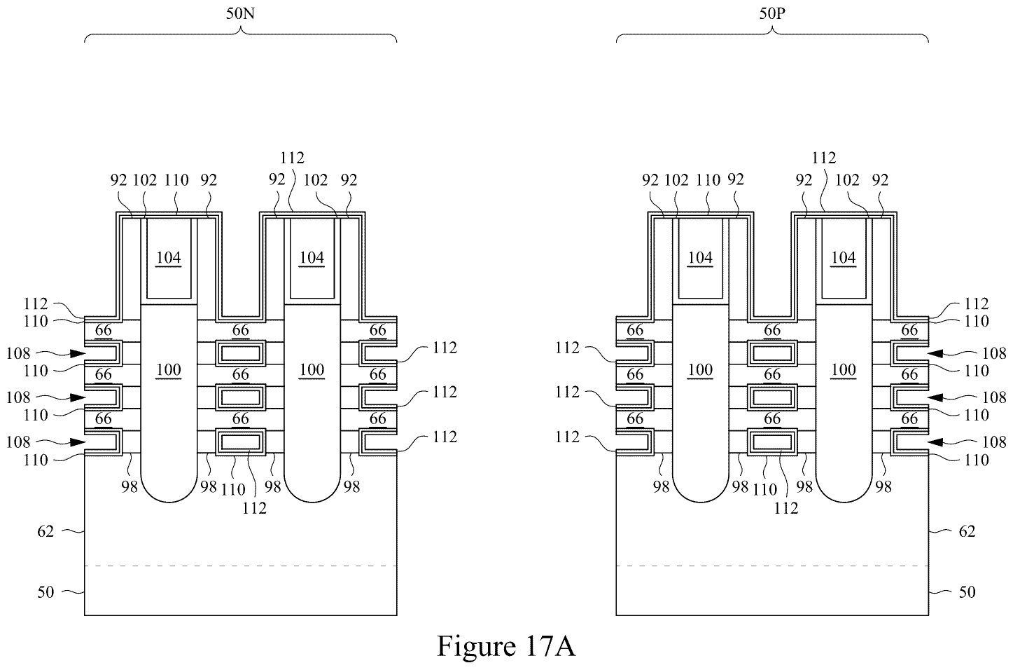

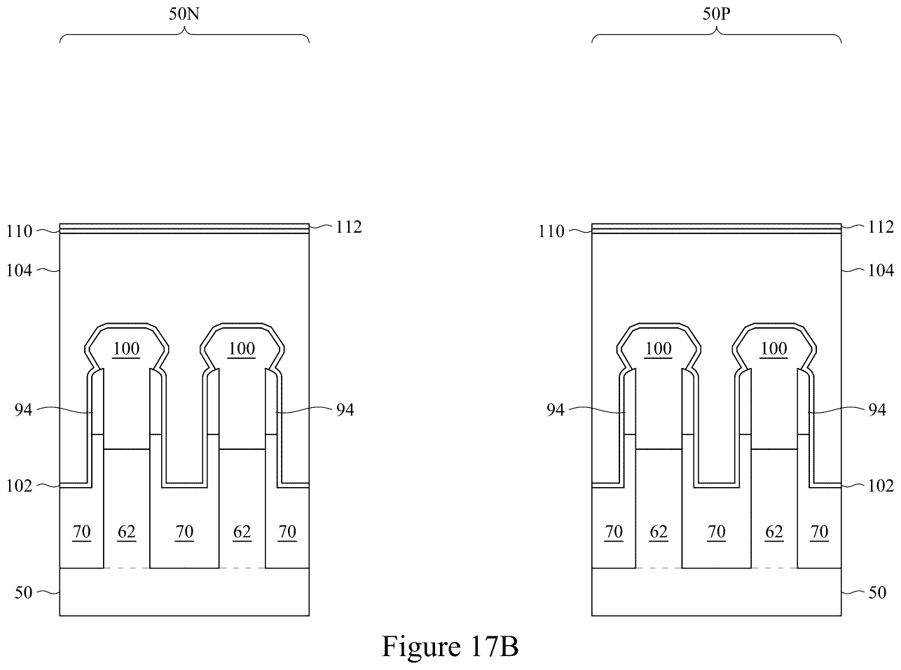

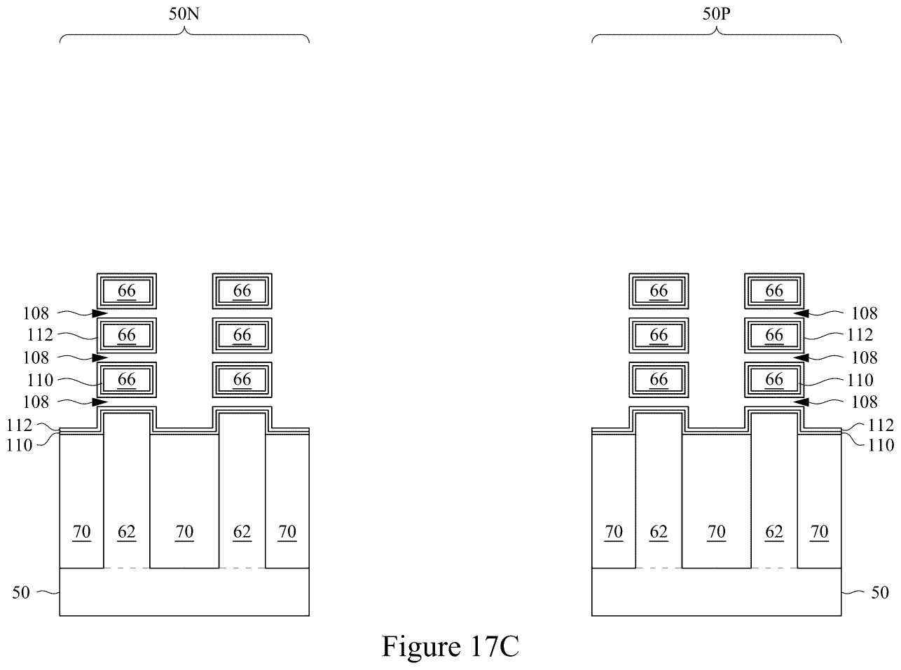

FIGS. 17A through 27C illustrate intermediate steps in the formation of gate electrodes 120 as part of the replacement gates, in accordance with some embodiments. The gate electrodes 120 comprise one or more work function tuning layers (“WF layers”) and a fill material formed over the WF layers, described in greater detail below. The gate electrodes 120 may include any number of WF layers, any number of barrier layers, any number of glue layers, or other layers.

In FIGS. 17A-17C, a first WF layer 112 is deposited over the gate dielectrics 110, in accordance with some embodiments. The first WF layer 112 may be deposited conformally within the openings 108. For example, the first WF layer 112 is deposited over the top surfaces, the sidewalls, and the bottom surfaces of the channel regions of the nanostructures 66. In some embodiments, the first WF layer 112 is deposited in both the n-type region 50N and in the p-type region 50P using the same deposition process.

The first WF layer 112 comprises any acceptable material(s) to tune a work function of a device in the p-type region 50P to a desired amount given the application of the device to be formed. Accordingly, the first WF layer 112 may be considered a “p-type work function tuning layer” or “p-type WF layer” in some cases. For example, the first WF layer 112 may be subsequently used as a work function tuning layer for nanostructure-FETs in the p-type region 50P. The first WF layer 112 may be deposited using any acceptable deposition process. For example, when the first WF layer 112 is a p-type work function tuning layer, it may be formed of a p-type work function metal (PWFM) such as titanium nitride (TiN), tantalum nitride (TaN), combinations thereof, or the like, which may be deposited by ALD, CVD, PVD, or the like. Although the first WF layer 112 is shown as being single layered, the first WF layer 112 can be multi-layered. For example, the first WF layer 112 can include a layer of titanium nitride and a layer of tantalum nitride. Other materials or combinations of materials are possible.

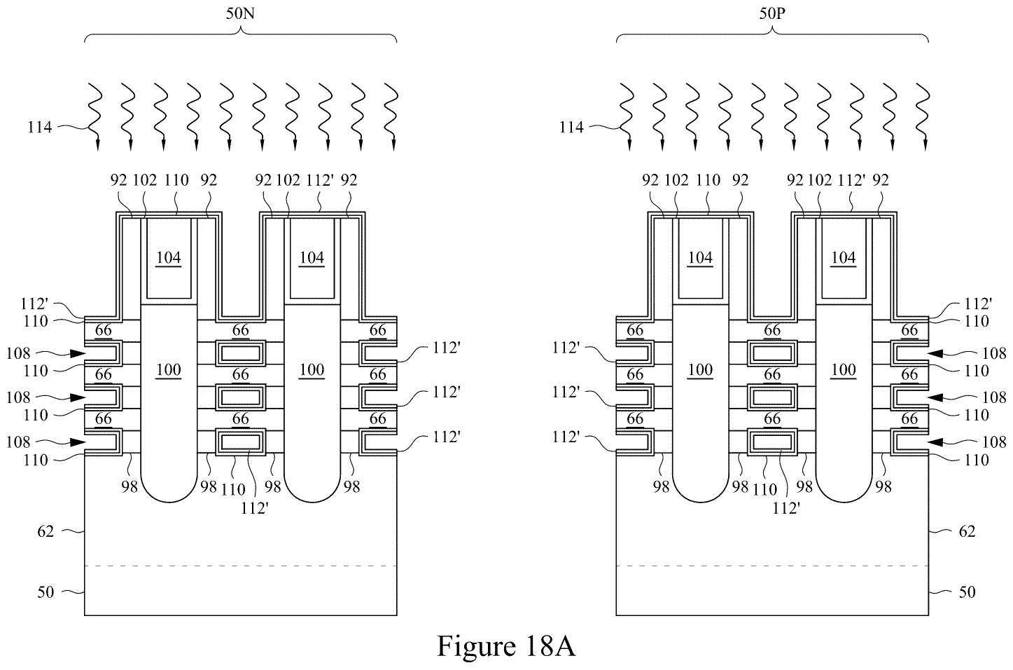

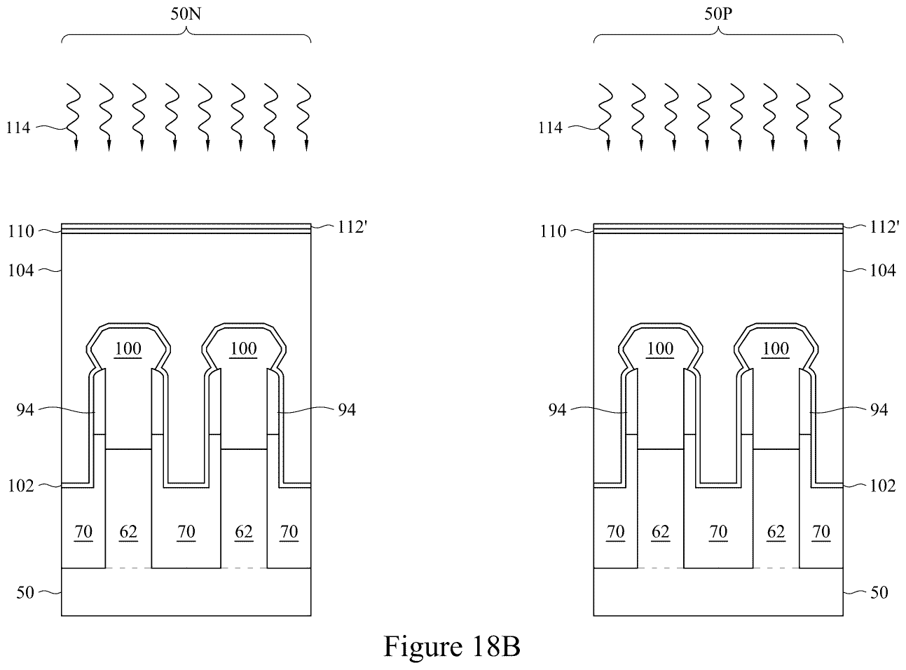

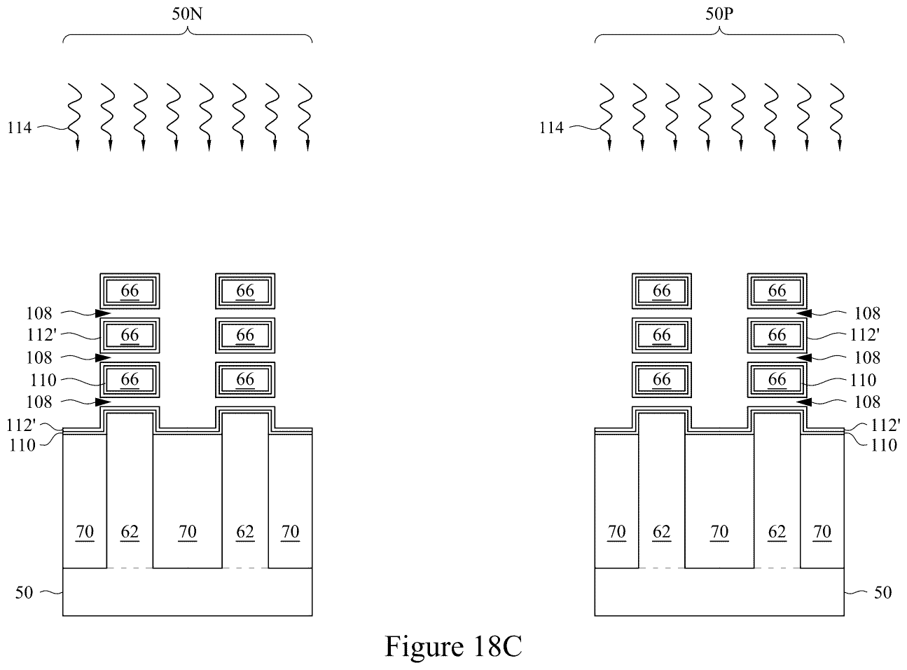

In FIGS. 18A-18C, a silicon soak process 114 is performed on the first WF layer 112, in accordance with some embodiments. After performing the silicon soak process 114, the first WF layer 112 is referred to herein as the post-soak first WF layer 112′ or simply as the first WF layer 112′. The silicon soak process 114 forms a silicon-containing layer on the first WF layer 112 that reduces the subsequent formation of a second WF layer, described in greater detail below. The silicon soak process 114 comprises placing the substrate 50 in a chamber and exposing surfaces of the first WF layer 112 to a silicon-based precursor for a duration of time. For example, in some embodiments, the silicon soak process 114 comprises placing the substrate 50 into a chamber, introducing one or more silicon-based precursors into the chamber, and then closing the inlets and exhausts of the chamber for a predetermined time. The silicon-based precursor adsorbs or reacts with surfaces of the first WF layer 112, and the silicon-based precursor is exhausted from the chamber after the predetermined time has elapsed. The chamber may be a process chamber of an ALD deposition system, a plasma-enhanced ALD (PEALD) deposition system, a plasma-enhanced cyclic CVD (PECCVD) system, a pulsed CVD system, an implantation system, or any other suitable process chamber or other suitable chamber. In this manner, in some cases, the silicon soak process 114 may be considered an ALD process, a PEALD process, a PECVD process, a pulsed CVD process, or the like.

The silicon soak process 114 can be performed at a temperature in the range of about 0° C. to about 900° C. and at a pressure in the range of about 0.5 Torr to about 20 Torr, e.g., by maintaining the chamber at such a temperature and/or pressure. The silicon soak process 114 can be performed for a duration in the range of about 1 second to about 600 seconds, e.g., by keeping the silicon-based precursor in the chamber for such a duration. Exemplary silicon-based precursors may comprise molecules such as (but not limited to) silanes, organosilanes, or the like. Silanes May include silane (SiH₄), disilane (Si₂H₆), trisilane (Si₃H₈), tetrasilane (Si₄H₁₀), the like, or any combination thereof. Organosilanes may include compounds with the empirical formula RySixH(2x+2−y), where R is independently methyl, ethyl, propyl, or butyl, or the like. For example, organosilanes may include methylsilane ((CH₃)SiH₃), dimethylsilane ((CH₃)₂SiH₂), ethylsilane ((CH₃CH₂)SiH₃), methyldisilane ((CH₃)Si₂H₅), dimethyldisilane ((CH₃)₂Si₂H₄), hexamethyldisilane ((CH₃)₆Si₂), tris(dimethylamino)silane (TDMAS), the like, or any combination thereof. Other parameters or precursors are possible. Controlling the parameters or precursors used for the silicon soak process 114 can change the thickness (e.g., number of monolayers), composition (e.g., % silicon), or other characteristics of the silicon-containing layer formed by the silicon soak process 114.

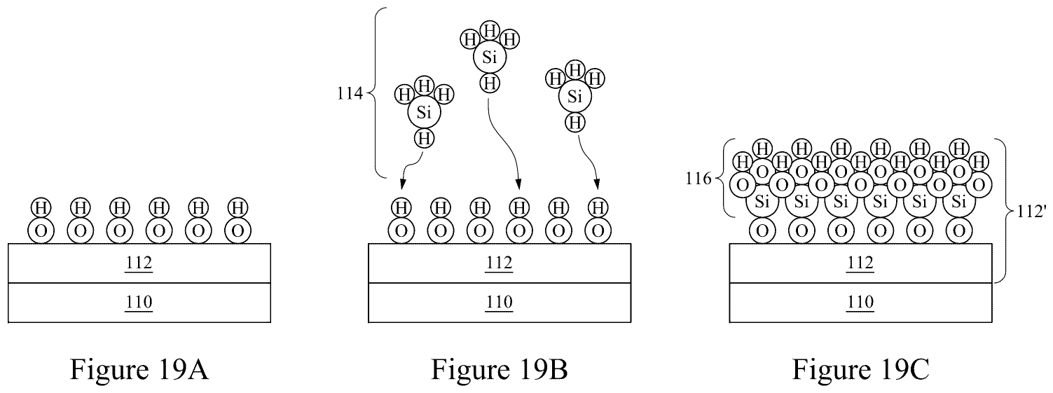

FIGS. 19A, 19B, and 19C illustrate intermediate steps in the formation of a post-soak first WF layer 112′ using a silicon soak process 114, in accordance with some embodiments. FIG. 19A schematically illustrates a cross-section of a portion of the first WF layer 112 covering the gate dielectrics 110 prior to the silicon soak process 114. FIG. 19B schematically illustrates the first WF layer 112 and the gate dielectrics 110 during the silicon soak process 114. FIG. 19C schematically illustrates the gate dielectrics 110 and the post-soak first WF layer 112′ including a silicon-containing layer 116 after completion of the silicon soak process 114. FIGS. 19A-19C are intended as explanatory illustrations, and other materials or configurations are possible.

FIG. 19A illustrates the first WF layer 112 after deposition on the gate dielectrics 110, similar to the step shown in FIGS. 17A-17C. For example, the first WF layer 112 may comprise titanium nitride or the like. As shown schematically in FIG. 19A, the surface of the first WF layer 112 may be covered in hydroxide surface ligands (e.g., —OH bonds) or the like.

In FIG. 19B, the first WF layer 112 is subjected to the silicon soak process 114. The silicon-based precursors, represented schematically in FIG. 19B by silane molecules, impinge or adsorb onto the surface of the first WF layer 112 and react with the hydroxide surface ligands. The reaction between the silicon-based precursors and the hydroxide surface ligands allows the silicon of the silicon-based precursors to bond to the oxygen at the surface of the first WF layer 112. In this manner, a silicon-containing layer 116 (see FIG. 19C) may be formed at the surface of the first WF layer 112 as more silicon-based precursors react with the hydroxide surface ligands.

In FIG. 19C, the silicon soak process 114 has been performed, forming a silicon-containing layer 116 covering the first WF layer 112. The first WF layer 112 and the overlying silicon-containing layer 116 together form the post-soak first WF layer 112′. The silicon-containing layer 116 may comprise one silicon-containing layer (e.g., a silicon-containing monolayer) or a plurality of silicon-containing layers (e.g., a silicon-containing multi-layer). For example, in some embodiments the silicon-containing layer 116 may comprise a monolayer of silicon oxide (e.g., SiO₂) or multi-layers of silicon oxide (e.g., multi-layers of SiO₂), though other layer compositions are possible. In this manner, hydroxide —OH bonds on the surfaces of the first WF layer 112 can be replaced by Si—O bonds (e.g., silicon-oxygen bonds) and/or Si—OH bonds (e.g., silicon-hydroxide bonds) using the silicon soak process 114. In some cases, the silicon-containing layer 116 may have a thickness in the range of about 5 Å to about 50 Å.

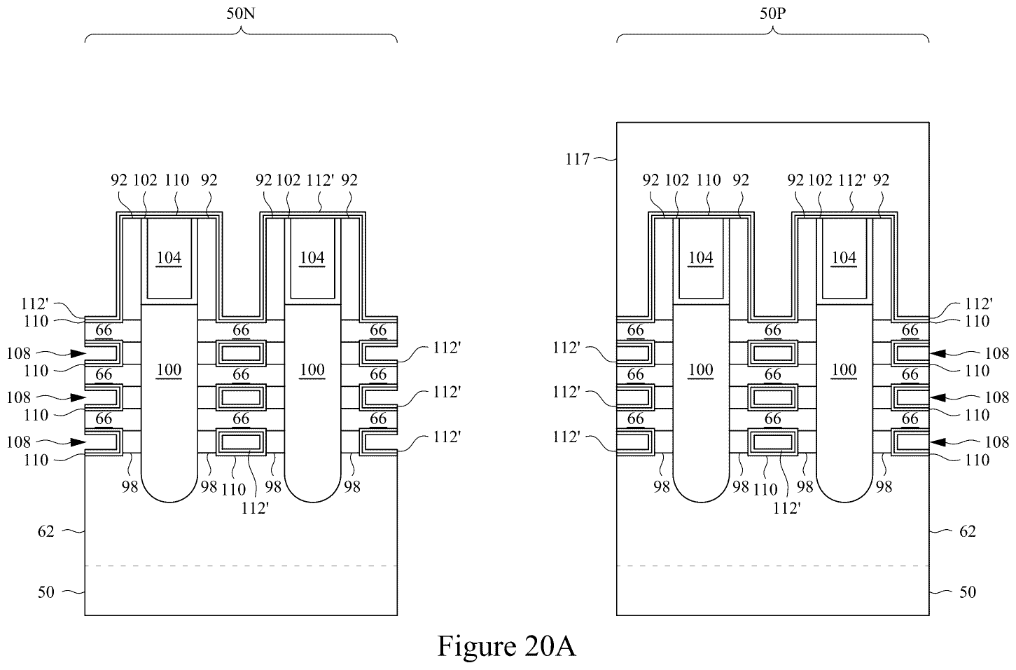

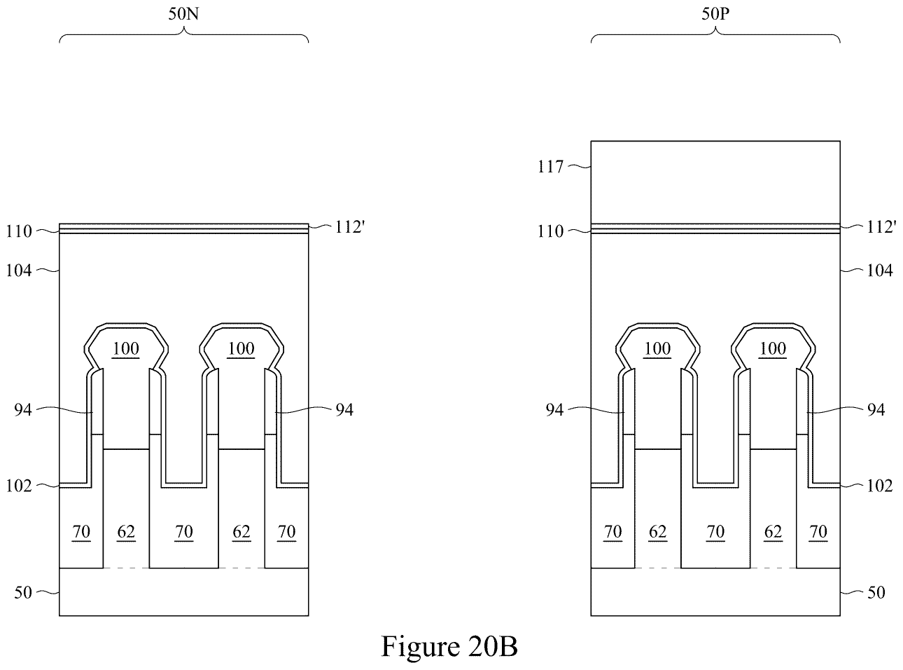

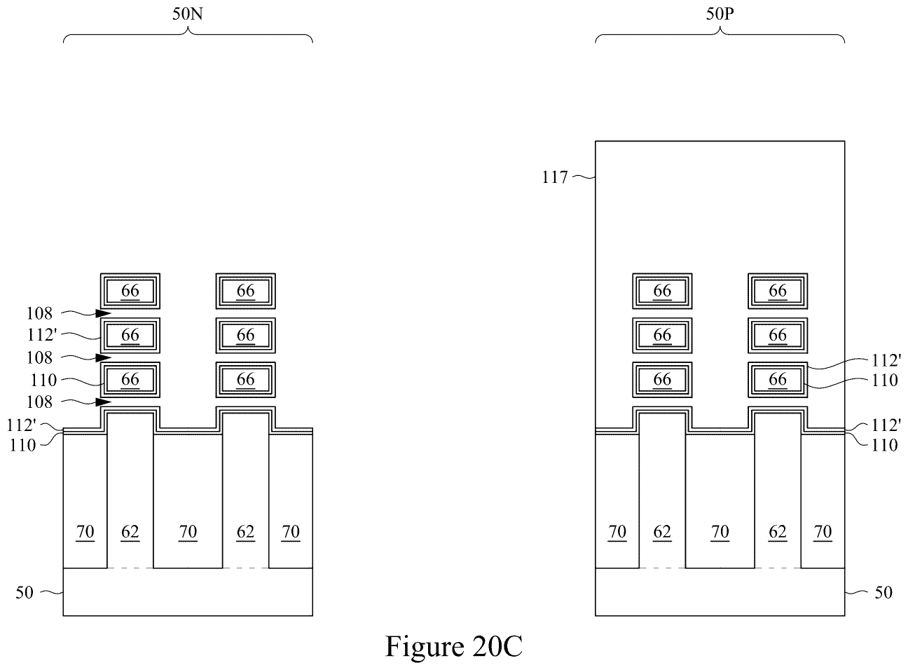

In FIGS. 20A-20C, a mask 117 is formed over the p-type region 50P, in accordance with some embodiments. The mask 117 may include, for example, a photoresist, a multi-layer photoresist structure, an anti-reflective coating (e.g. a BARC layer), or the like. The mask 117 may be formed using a suitable technique (e.g., spin-on or the like) and patterned using suitable photolithographic techniques to expose the n-type region 50N. In this manner, the first WF layer 112′ in the p-type region 50P is protected and the first WF layer 112′ in the n-type region 50N is exposed.

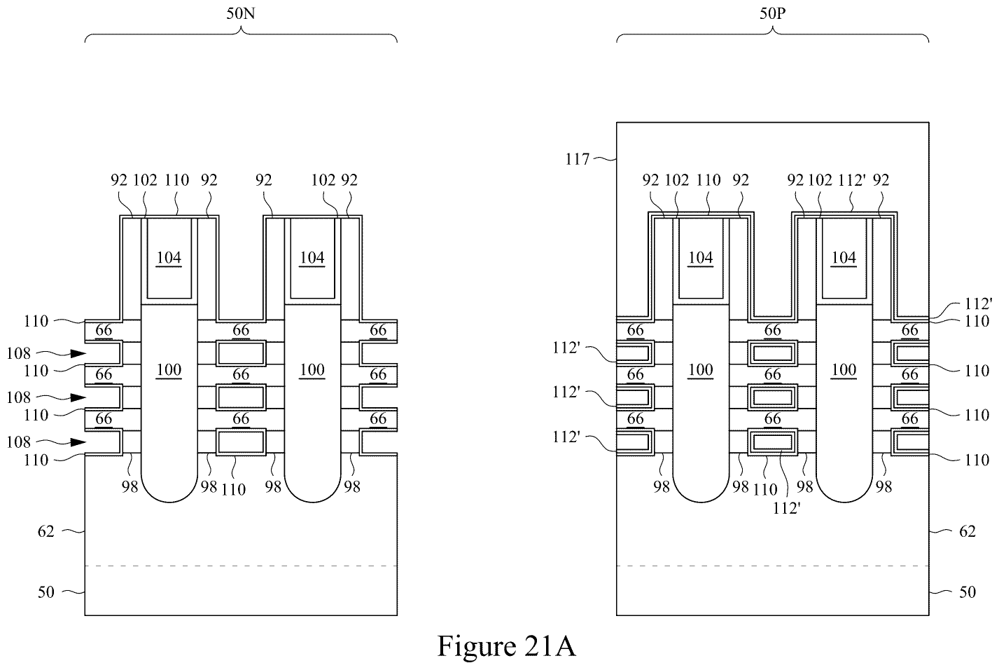

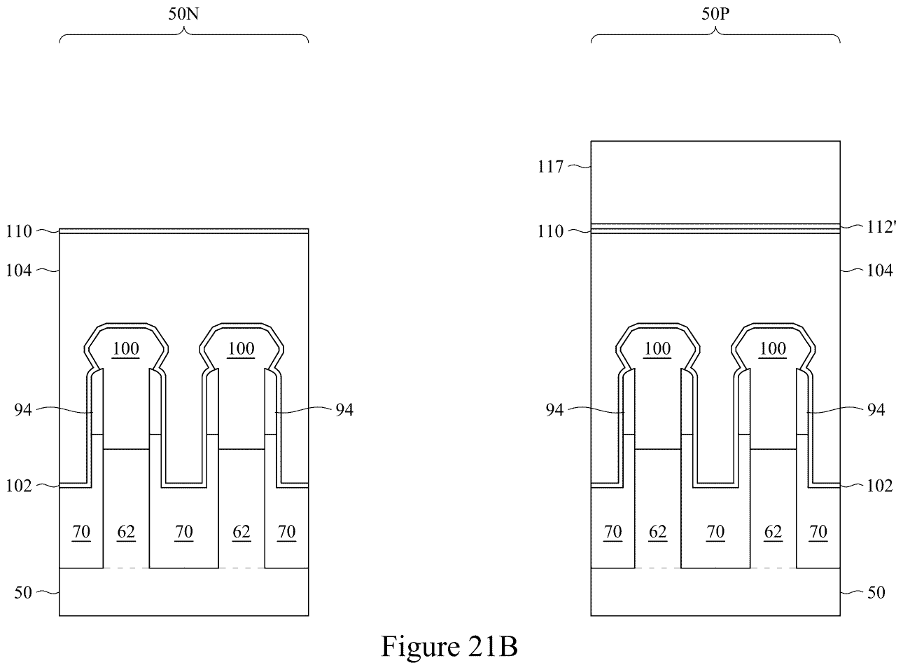

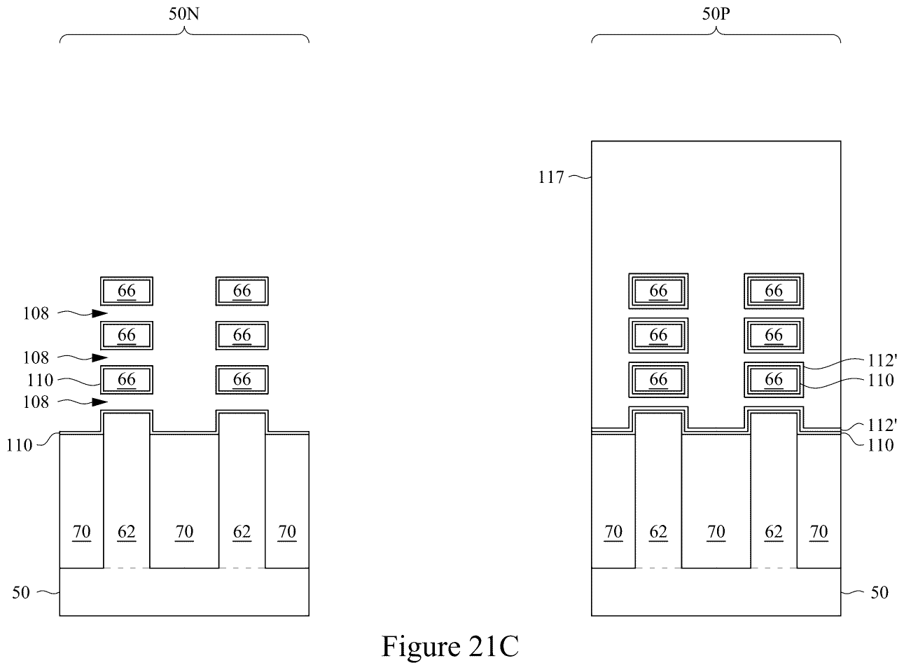

In FIGS. 21A-21C, an etch process is performed to remove the first WF layer 112′ in the n-type region 50N, in accordance with some embodiments. The etch process removes the silicon-containing layer 116 and the first WF layer 112 to expose the underlying gate dielectrics 110 of the n-type region 50N. The mask 117 protects the first WF layer 112′ in the p-type region 50P from the etch process. The etch process may include a wet etch process and/or a dry etch process. In some cases, the etch process may selectively etch the first WF layer 112′ with little or no etching of the gate dielectrics 110.

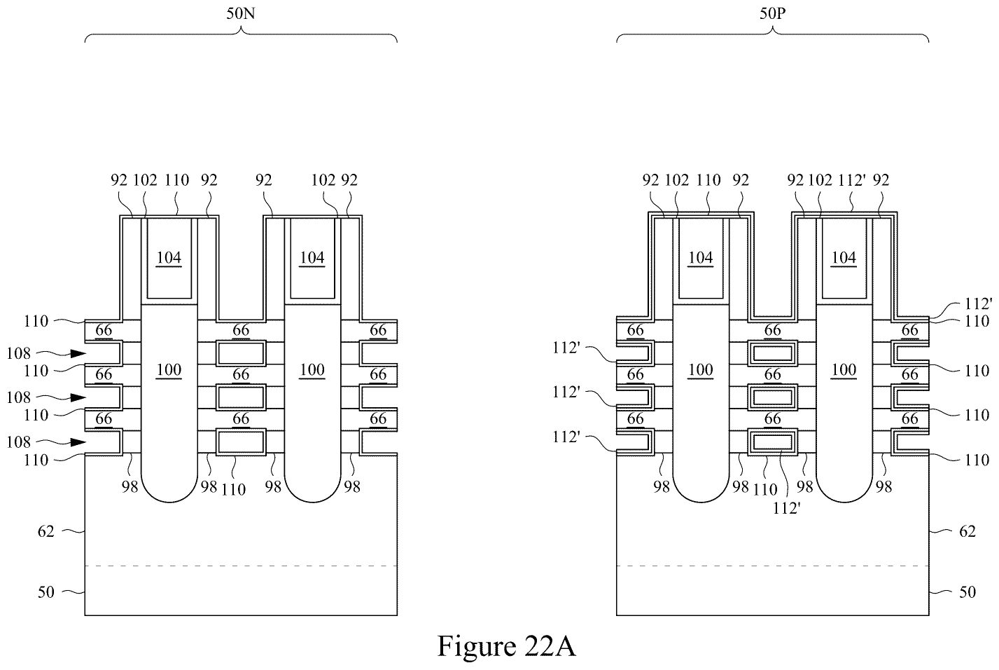

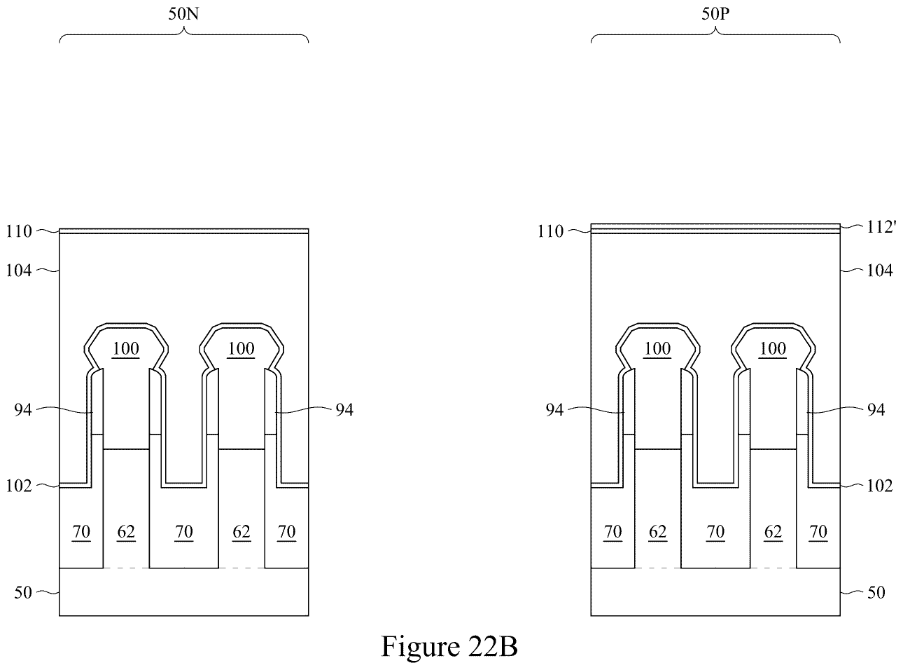

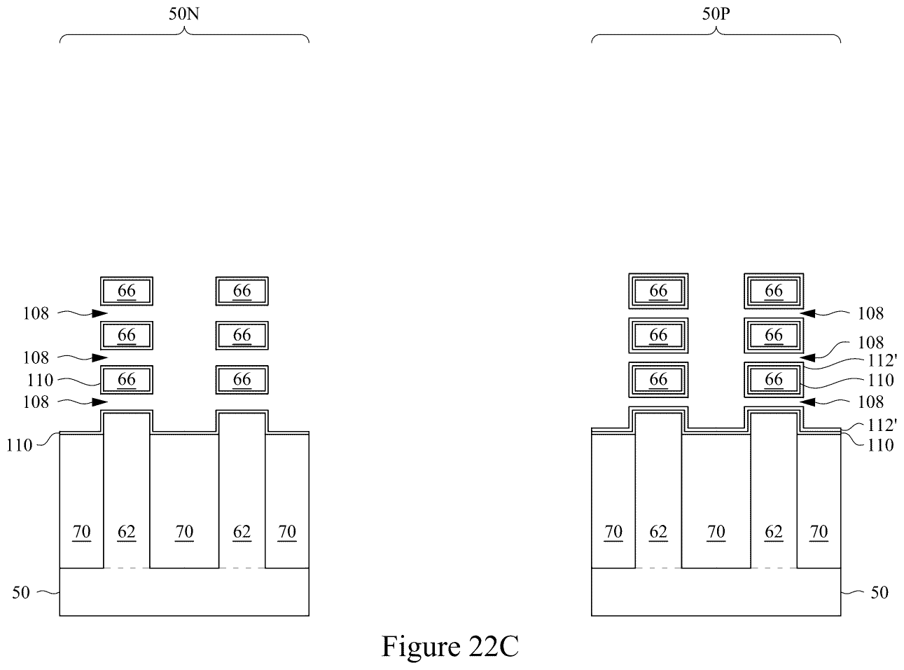

In FIGS. 22A-22C, the mask 117 is removed from the p-type region 50P. The mask 117 may be removed using a suitable technique, such as an etch process, an ashing process, or the like. After removing the mask 117, the gate dielectrics 110 is exposed in the n-type region 50N and the first WF layer 112′ is exposed in the p-type region 50P.

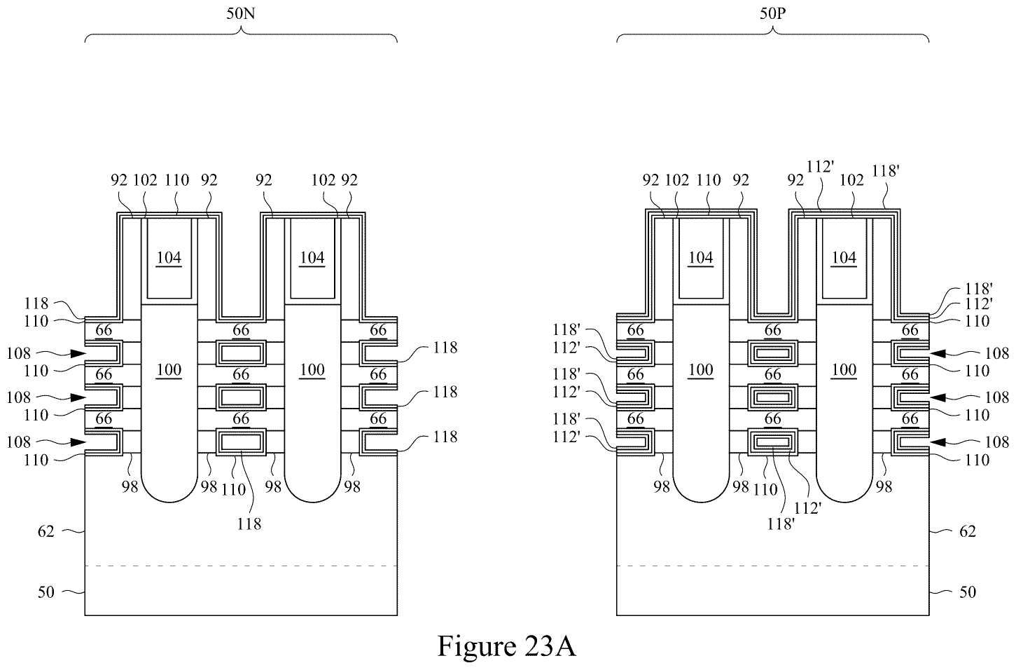

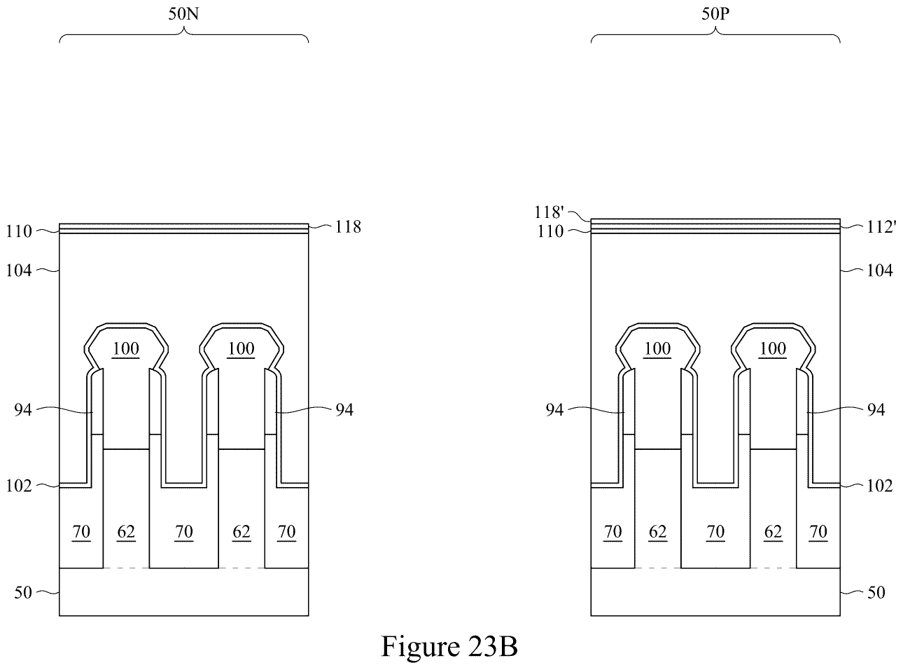

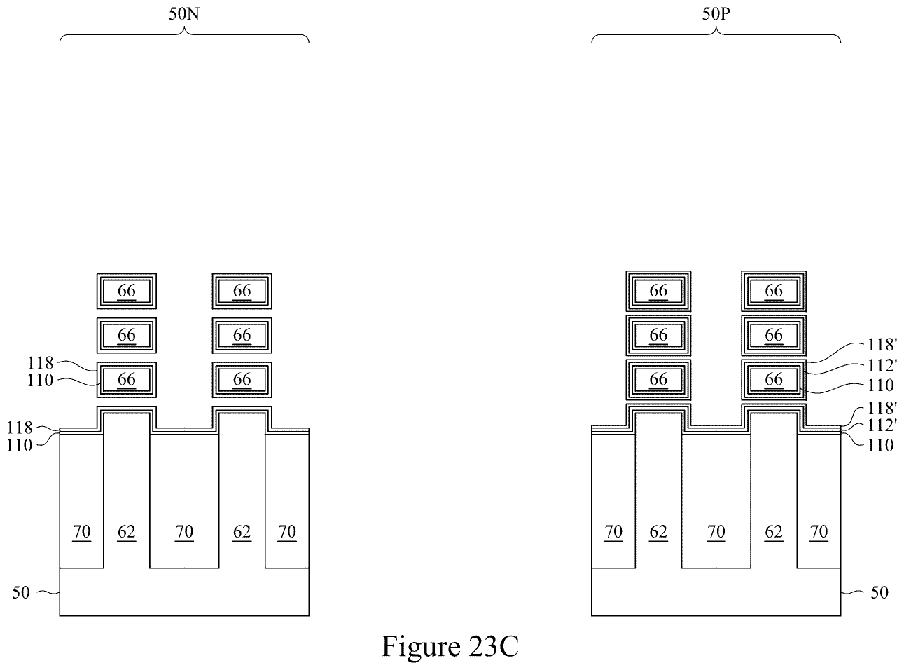

In FIGS. 23A-23C, a second WF layer 118 is deposited over the gate dielectrics 110 in the n-type region 50N and over the first WF layer 112′ in the p-type region 50P, in accordance with some embodiments. The second WF layer 118 may be deposited conformally within the openings 108. For example, the second WF layer 118 is deposited over the top surfaces, the sidewalls, and the bottom surfaces of the channel regions of the nanostructures 66. The second WF layer 118 is deposited in both the n-type region 50N and in the p-type region 50P using the same deposition process. As explained in greater detail below, the silicon-containing layer 116 in the first WF layer 112′ retards the formation of the second WF layer 118 in the p-type region 50P during the deposition process. Accordingly, the second WF layer 118 formed in the p-type region 50P may be thinner than the second WF layer 118 formed in the n-type region 50N. In some cases, the second WF layer 118 formed on the first WF layer 112′ in the p-type region 50P is referred to herein as the second WF layer 118′ to distinguish from the second WF layer 118 formed on the gate dielectrics 110 in the n-type region 50N. In other cases, the second WF layer 118 may refer to both the second WF layer 118 formed in the n-type region 50N and the second WF layer 118′ formed in the p-type region 50P, depending on context. Forming a thinner second WF layer 118 in the p-type region 50P can reduce the amount of second WF layer 118 material that undesirably diffuses into the first WF layer 112, described in greater detail below.

The second WF layer 118 comprises any acceptable material(s) to tune a work function of a device in the n-type region 50N to a desired amount given the application of the device to be formed. Accordingly, the second WF layer 118 may be considered an “n-type work function tuning layer” or “n-type WF layer” in some cases. For example, the second WF layer 118 may be subsequently used as a work function tuning layer for nanostructure-FETs in the n-type region 50N. The second WF layer 118 may be deposited using any acceptable deposition process. For example, when the second WF layer 118 is a n-type work function tuning layer, it may be formed of a n-type work function metal (NWFM) such as titanium aluminum (TiAl), titanium aluminum carbide (TiAlC), titanium aluminum nitride (TiAlN), combinations thereof, or the like, which may be deposited by ALD, CVD, PVD, or the like. Although the second WF layer 118 is shown as being single layered, the second WF layer 118 can be multi-layered.

In embodiments in which the second WF layer 118 is an n-type work function tuning layer, it may include a metal element that is suitable for tuning the threshold voltages of n-type devices, such as aluminum. In some cases, aluminum in an n-type work function tuning layer can diffuse into underlying layers during subsequent process steps, especially during process steps at elevated temperatures. For structures in which a n-type work function tuning layer is deposited over a p-type work function tuning layer, the aluminum in the n-type work function tuning layer can diffuse into the p-type work function tuning layer, shifting the effective work function of the p-type work function tuning layer. Aluminum or other n-type work function elements that diffuse into the p-type work function tuning layer can reduce the accuracy or uniformity of the work function tuning in the p-type region 50P, and can shift the effective work function of the p-type work function tuning layer in ways that negatively impact device performance. For example, the presence of aluminum in the p-type work function tuning layer can undesirably decrease the flat band voltage in a p-type MOS capacitor or can undesirably increase the threshold voltage of a p-type transistor (e.g., a p-type MOSFET, a p-type nanostructure-FET, or the like).

Forming a thinner n-type work function tuning layer over a p-type work function tuning layer can reduce the amount of aluminum available to diffuse into the p-type work function tuning layer, and thus can reduce the amount of aluminum that diffuses into the p-type work function tuning layer. By reducing the amount of aluminum that diffuses into the p-type work function tuning layer, the amount that the work function of the p-type work function tuning layer is shifted by the presence of aluminum can be reduced, thereby increasing device performance and device uniformity.

Subjecting the first WF layer 112 of the p-type region 50P to a silicon soak process 114 as described herein can modify the surface of the first WF layer 112 in a manner that impedes the subsequent growth of the second WF layer 118 on the first WF layer 112. In this manner, a thinner second WF layer 118′ can be formed on the first WF layer 112′ in the p-type region 50P while forming the second WF layer 118 in the n-type region 50N. Thus, the use of the silicon soak process 114 as described herein can reduce aluminum diffusion into the first WF layer 112, improving work function tuning accuracy, improving device performance, and improving device uniformity.

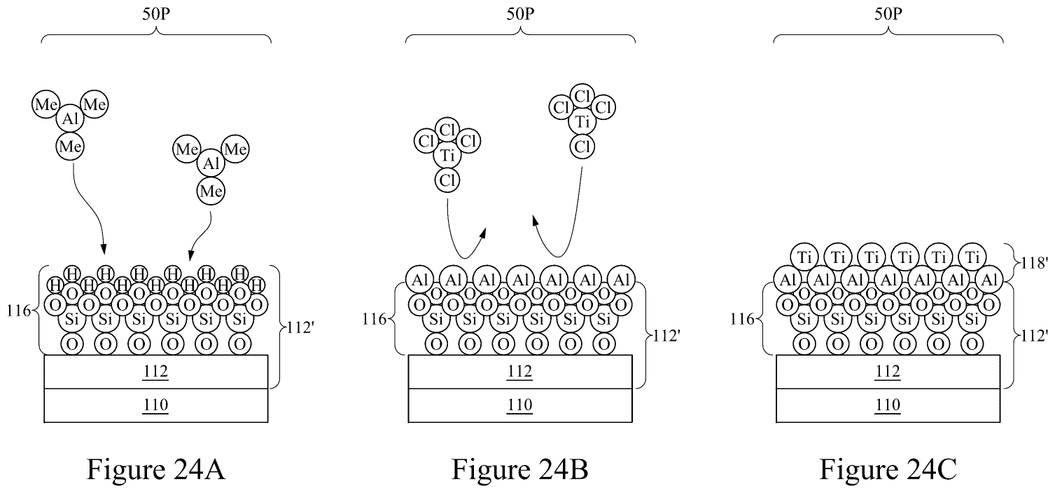

Turning to FIGS. 24A-24C, intermediate steps in the formation of a second WF layer 118′ on a first WF layer 112′ are shown, in accordance with some embodiments. FIGS. 24A and 24B schematically illustrate cross-sections of a portion of the first WF layer 112′ during deposition of the second WF layer 118′. FIG. 24C schematically illustrates the formation of a portion of a second WF layer 118′. FIGS. 24A-24C illustrate portions of the first WF layer 112′ in the p-type region 50P, which may be similar to the views shown in FIGS. 19A-C. FIGS. 24A-24C are intended as explanatory illustrations, and other materials or configurations are possible.

FIGS. 24A-24C illustrate an embodiment in which the second WF layer 118 comprises titanium aluminum (TiAl) deposited using an aluminum-based precursor and a titanium-based precursor, though other materials or precursors are possible. For example, FIG. 19A illustrates the use of trimethylaluminium (TMA) (Al₂(CH₃)₆) as an aluminum-based precursor, and FIG. 24B illustrates the use of titanium tetrachloride (TiCl₄) as a titanium-based precursor, though other precursors are possible.

In FIG. 24A, the first WF layer 112′ is exposed to the aluminum-based precursor, which adsorb on and react with the Si—O/Si—OH bonds of the silicon-containing layer 116 to form SiOAlₓ comprising Al—O—Si bonds (e.g., aluminum-oxygen-silicon bonds, shown in FIG. 24B). For example, without the presence of the silicon-containing layer 116, the TMA molecules react with the —OH bonds (see FIG. 19A) on the first WF layer 112 to form Al-methyl bonds at the surface. However, the Si—O/Si—OH bonds in the silicon-containing layer 116 cause the TMA molecules to form Al—O—Si bonds over the first WF layer 112 instead of Al-methyl bonds. FIG. 24B shows a single monolayer of SiOAlₓ, but in other embodiments, multiple layers of SiOAlₓ may be formed.

In FIG. 24B, after forming Al—O—Si bonds, the first WF layer 112′ is exposed to the titanium-based precursor. However, the titanium-based precursor does not react as readily with the Al—O—Si bonds as it does with other types of surfaces, such as Al-methyl bonds. Accordingly, the formation of the initial titanium aluminum layer is slowed due to the decreased rate of reactions between the titanium-based precursor and the Al—O—Si bonds. In this manner, a thinner second WF layer 118′ may be formed on the first WF layer 112′. FIG. 24C illustrates a second WF layer 118′ comprising a monolayer of titanium aluminum, but in other cases multiple cycles of the aluminum-based precursor and the titanium-based precursor may be used to form multi-layers of titanium aluminum.

In some cases, a second WF layer 118′ formed over a first WF layer 112′ with a silicon-containing layer 116 as described herein may have a thickness that is between about 0% and about 30% smaller than a thickness of a second WF layer 118 formed over a first WF layer 112 without a silicon-containing layer 116. In some cases, the second WF layer 118′ in the p-type region 50P may have a thickness in the range of about 10 Å to about 50 Å, though other thicknesses are possible.

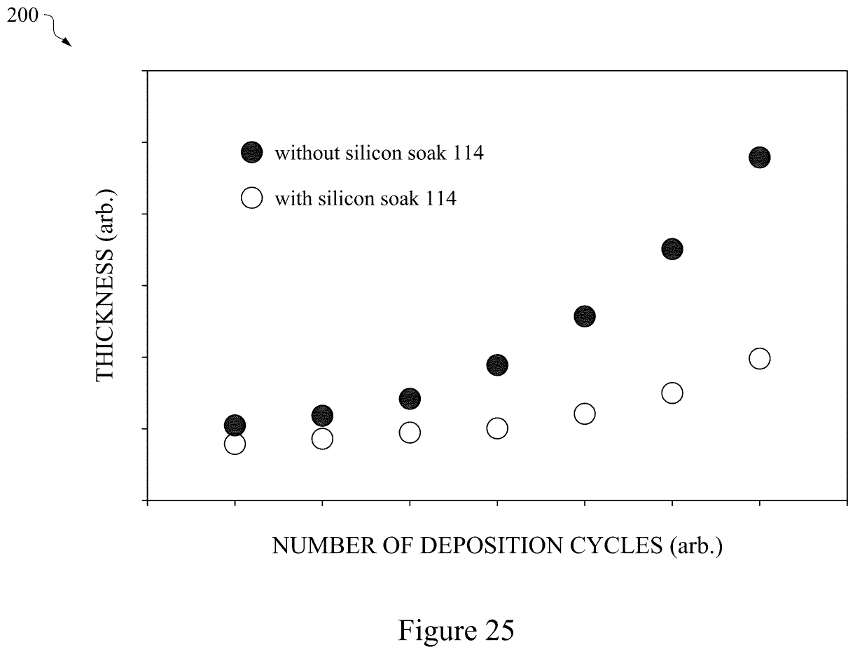

As an example, FIG. 25 illustrates a graph 200 of experimental data showing the thickness of titanium aluminum formed using multiple cycles. The closed circles correspond to titanium aluminum formed on a layer of titanium nitride that was not subjected to a silicon soak process 114, and the open circles correspond to titanium aluminum formed on a layer of titanium nitride that was subjected to a silicon soak process 114. As shown in FIG. 25, even over multiple growth cycles, the titanium aluminum formed over titanium nitride with a silicon soak process 114 has a smaller thickness than the titanium aluminum formed over titanium nitride without a silicon soak process 114. Accordingly, graph 200 shows that the silicon soak process 114 as described herein can reduce the growth rate and final thickness of the second WF layer 118. The graph 200 is representative, and other thicknesses or growth rates are possible.

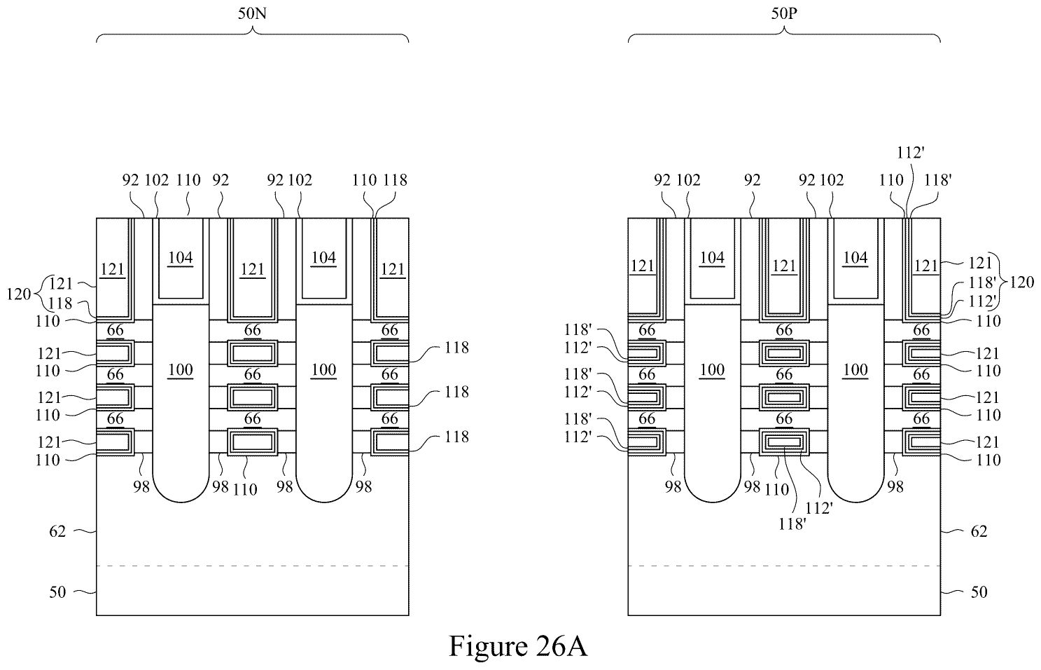

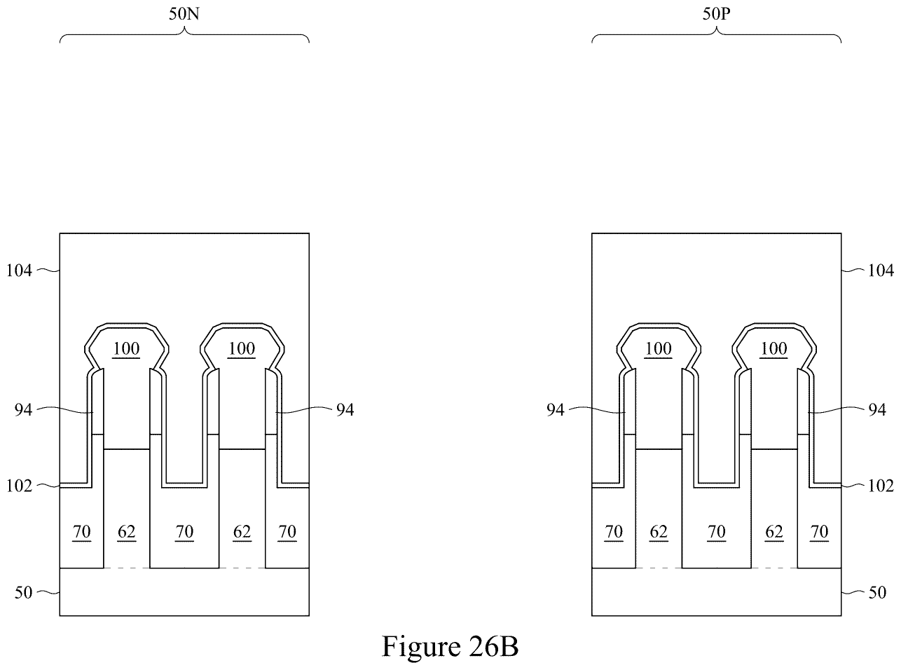

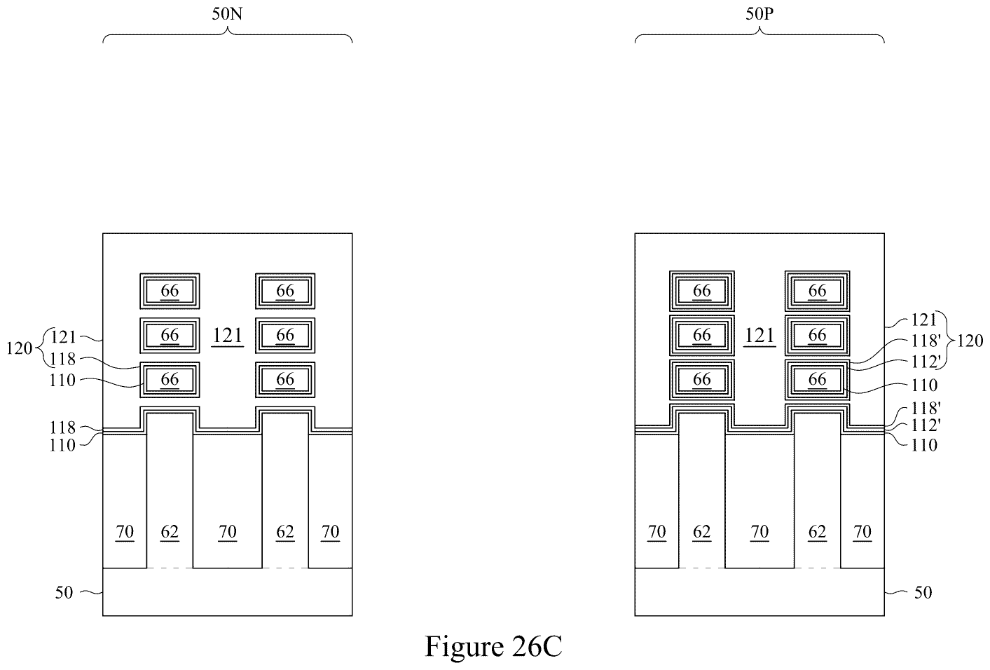

FIGS. 26A-26C illustrate the formation of fill material 121 to form gate electrodes 120 in the n-type region 50N and the p-type region 50P, in accordance with some embodiments. The fill material 121 is deposited over the second WF layer 118 in the n-type region 50N to form gate electrodes 120 in the n-type region 50N. The fill material 121 is deposited over the first WF layer 112′ and the second WF layer 118′ in the p-type region 50P to form gate electrodes 120 in the p-type region 50P. The fill material 121 fills the remaining portions of the openings 108. The fill material 121 may include any acceptable material of a low resistance. For example, the fill material 121 may be formed of a metal such as tungsten, aluminum, cobalt, ruthenium, combinations thereof or the like, which may be deposited by ALD, CVD, PVD, or the like. Other materials or deposition techniques are possible.

A removal process may then be performed to remove the excess portions of the gate dielectric layer(s) and the gate electrode layer(s), which excess portions are over the top surfaces of the first ILD 104, the CESL 102, and the gate spacers 92. In some embodiments, a planarization process such as a chemical mechanical polish (CMP), an etch-back process, a combination thereof, or the like may be utilized. The remaining portions of the gate dielectric layer(s) form the gate dielectrics 110, and the remaining portions of the gate electrode layer(s) form the gate electrodes 120. When a planarization process it utilized, the top surfaces of the gate spacers 92, the CESL 102, the first ILD 104, the gate dielectrics 110, and the gate electrodes 120 are level or coplanar (within process variations).

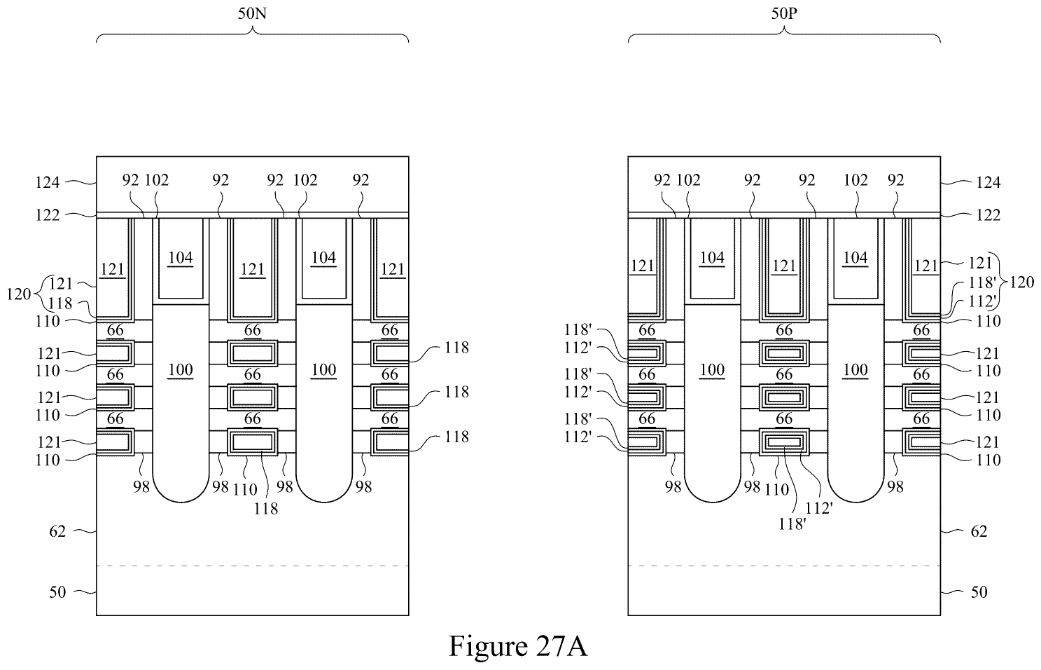

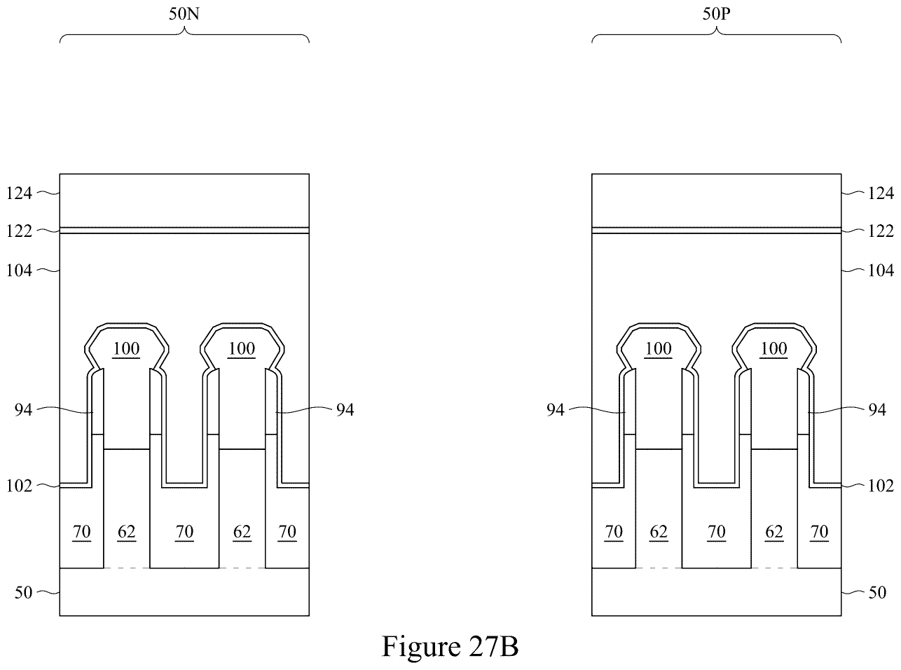

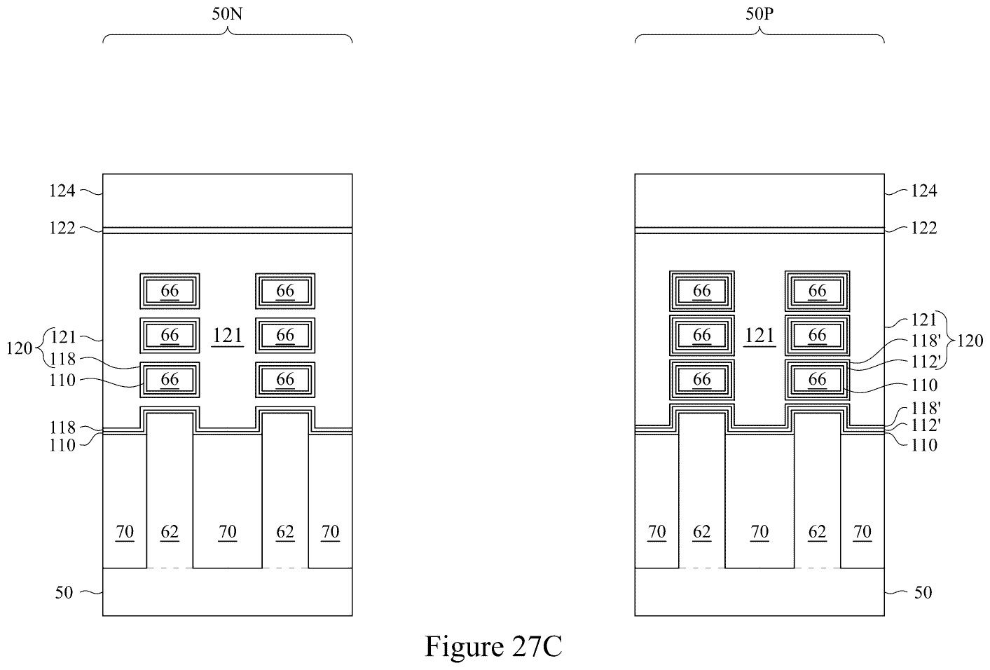

In FIGS. 27A-27C, a second ILD 124 is deposited over the gate spacers 92, the CESL 102, the first ILD 104, the gate dielectrics 110, and the gate electrodes 120. In some embodiments, the second ILD 124 is a flowable film formed by a flowable CVD method. In some embodiments, the second ILD 124 is formed of a dielectric material such as PSG, BSG, BPSG, USG, or the like, which may be formed by any suitable deposition process, such as CVD, PECVD, or the like.

In some embodiments, an etch stop layer (ESL) 122 is formed between the second ILD 124 and the gate spacers 92, the CESL 102, the first ILD 104, the gate dielectrics 110, and the gate electrodes 120. The ESL 122 may be formed of a dielectric material having a high etching selectivity from the etching of the second ILD 124, such as silicon nitride, silicon oxide, silicon oxynitride, or the like, which may be formed by any suitable deposition process, such as CVD, ALD, or the like.

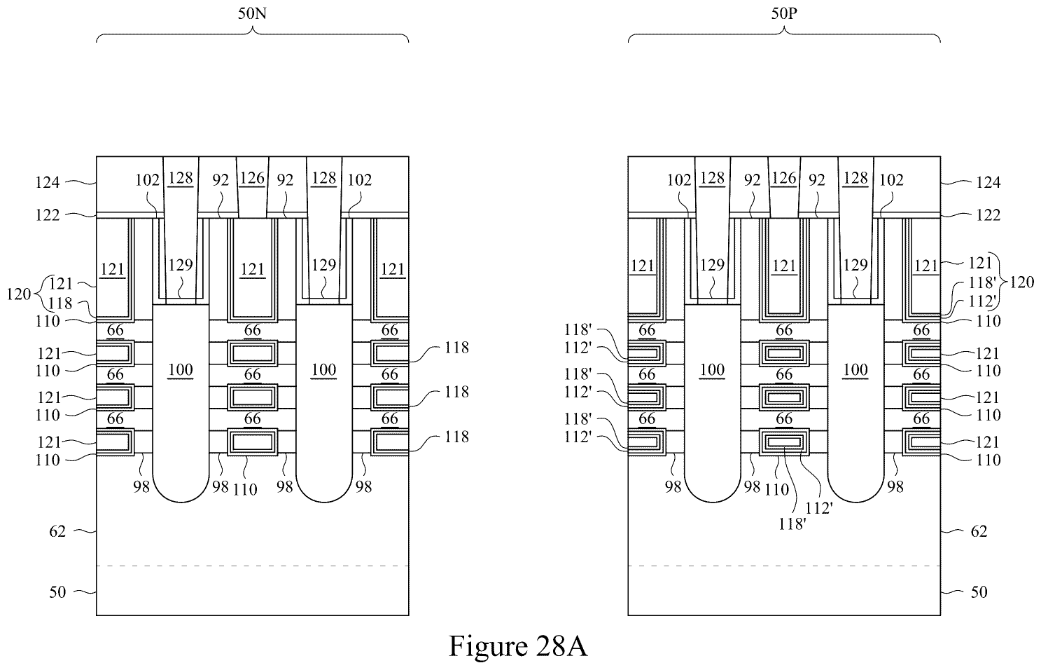

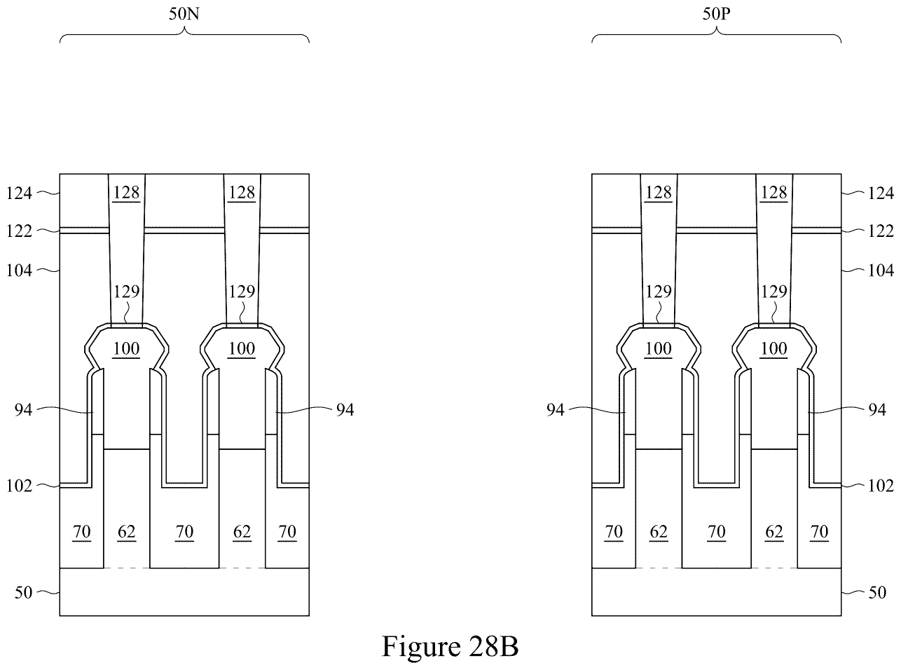

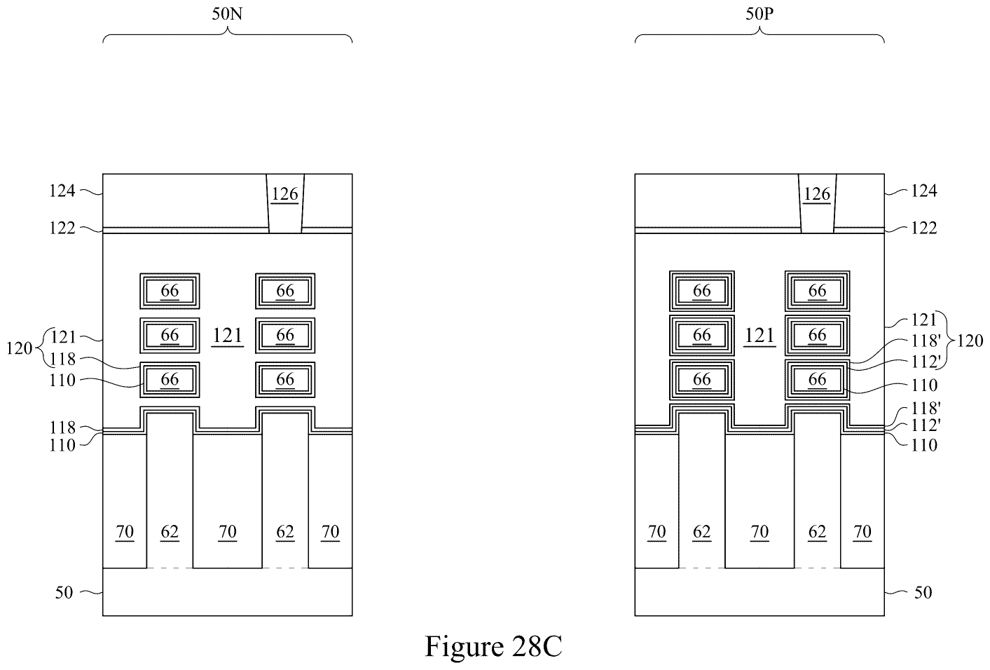

In FIGS. 28A-28C, gate contacts 126 and source/drain contacts 128 are formed to contact, respectively, the gate electrodes 120 and the source/drain regions 100. The gate contacts 126 may be physically and electrically coupled to the gate electrodes 120. The source/drain contacts 128 may be physically and electrically coupled to the source/drain regions 100.

As an example to form the gate contacts 126 and the source/drain contacts 128, openings for the gate contacts 126 are formed through the second ILD 124 and the ESL 122, and openings for the source/drain contacts 128 are formed through the second ILD 124, the ESL 122, the first ILD 104, and the CESL 102. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 124. The remaining liner and conductive material form the gate contacts 126 and the source/drain contacts 128 in the openings. The gate contacts 126 and the source/drain contacts 128 may be formed in distinct processes, or may be formed in the same process. Although shown as being formed in the same cross-sections, it should be appreciated that each of the gate contacts 126 and the source/drain contacts 128 may be formed in different cross-sections, which may avoid shorting of the contacts.

Optionally, metal-semiconductor alloy regions 129 are formed at the interfaces between the source/drain regions 100 and the source/drain contacts 128. The metal-semiconductor alloy regions 129 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon germanide regions formed of both a metal silicide and a metal germanide, or the like. The metal-semiconductor alloy regions 129 can be formed before the material(s) of the source/drain contacts 128 by depositing a metal in the openings for the source/drain contacts 128 and then performing a thermal annealing process. The metal can be any metal capable of reacting with the semiconductor materials (e.g., silicon, silicon carbide, silicon germanium, germanium, etc.) of the source/drain regions 100 to form a low-resistance metal-semiconductor alloy, such as nickel, cobalt, titanium, tantalum, platinum, tungsten, other noble metals, other refractory metals, rare earth metals, or their alloys. The metal may be formed by a deposition process such as ALD, CVD, PVD, or the like. After the thermal annealing process, a cleaning process, such as a wet clean, may be performed to remove any residual metal from the openings for the source/drain contacts 128, such as from surfaces of the metal-semiconductor alloy regions 129. The material(s) of the source/drain contacts 128 can then be formed on the metal-semiconductor alloy regions 129.

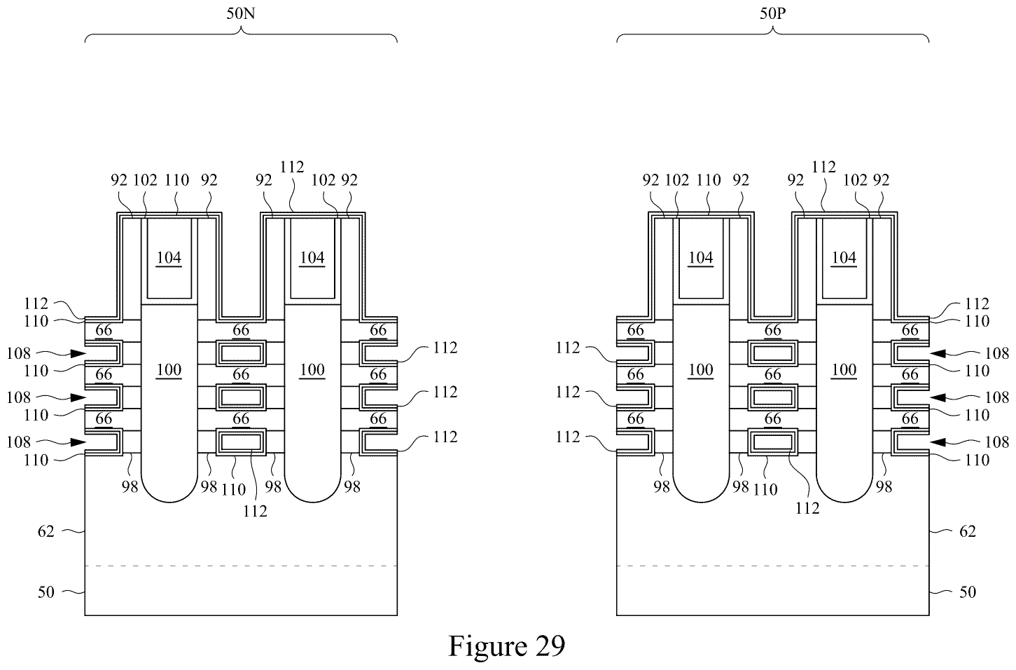

FIGS. 2 through 28C illustrate an embodiment in which the first WF layer 112 is removed from the n-type region 50N after performing the silicon soak process 114, but in other embodiments, the first WF layer 112 may be removed from the n-type region 50N before performing the silicon soak process 114. Accordingly, FIGS. 29-33 illustrate intermediate steps in the formation of nanostructure-FETs in which the first WF layer 112 is patterned before performing the silicon soak process 114. FIGS. 29-33 illustrate cross-sectional views along a similar cross-section as reference cross-section A-A′ in FIG. 1. Some of the process steps shown in FIGS. 29-33 may be similar to process steps described previously, and thus some similar details may not be repeated.

FIG. 29 shows a structure after the first WF layer 112 has been deposited over the n-type region 50N and the p-type region 50P, similar to the structure shown in FIG. 17A. The structure shown in FIG. 29 may be formed using similar techniques or materials described for forming the structure shown in FIGS. 17A-17C. The first WF layer 112 of FIG. 29 may be similar to that described previously for FIGS. 17A-C, and may be deposited using similar techniques.

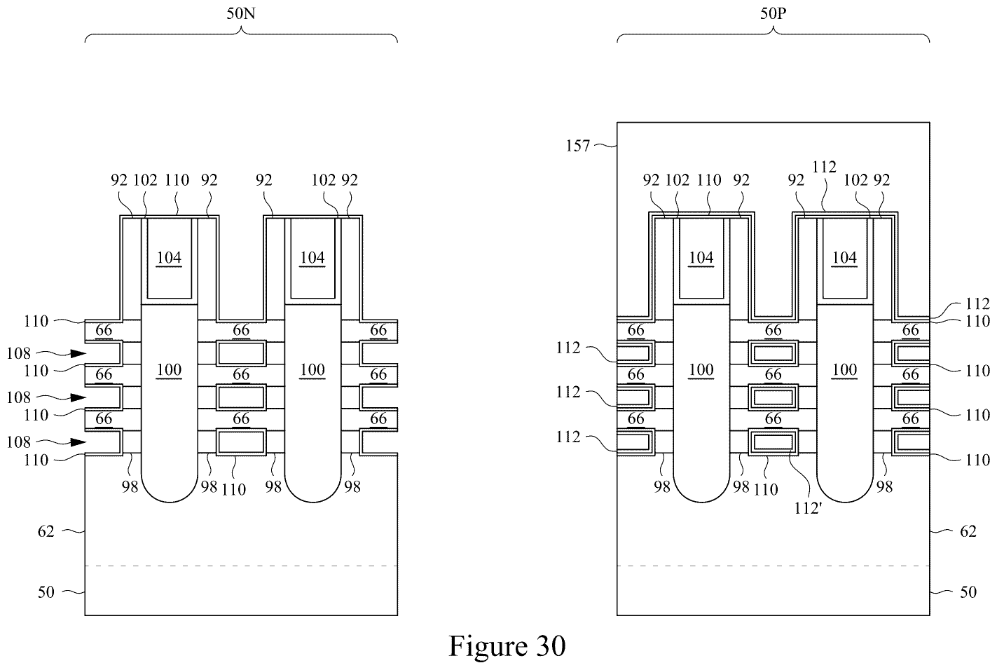

In FIG. 30, a mask 157 is formed over the p-type region 50P and the first WF layer 112 in the n-type region 50N is removed, in accordance with some embodiments. The mask 157 may include, for example, a photoresist or the like, and may be similar to the mask 117 described previously for FIGS. 20A-20C. The mask 157 may be formed using a suitable technique (e.g., spin-on or the like) and patterned using suitable photolithographic techniques to expose the n-type region 50N. In this manner, the first WF layer 112 in the p-type region 50P is protected and the first WF layer 112 in the n-type region 50N is exposed.

Still referring to FIG. 30, an etch process is performed to remove the first WF layer 112 in the n-type region 50N, in accordance with some embodiments. The etch process removes the first WF layer 112 to expose the underlying gate dielectrics 110 of the n-type region 50N. The mask 157 protects the first WF layer 112 in the p-type region 50P from the etch process. The etch process may include a wet etch process and/or a dry etch process. In some cases, the etch process may selectively etch the first WF layer 112 with little or no etching of the gate dielectrics 110. The etch process may be similar to that described previously for FIGS. 21A-21C.

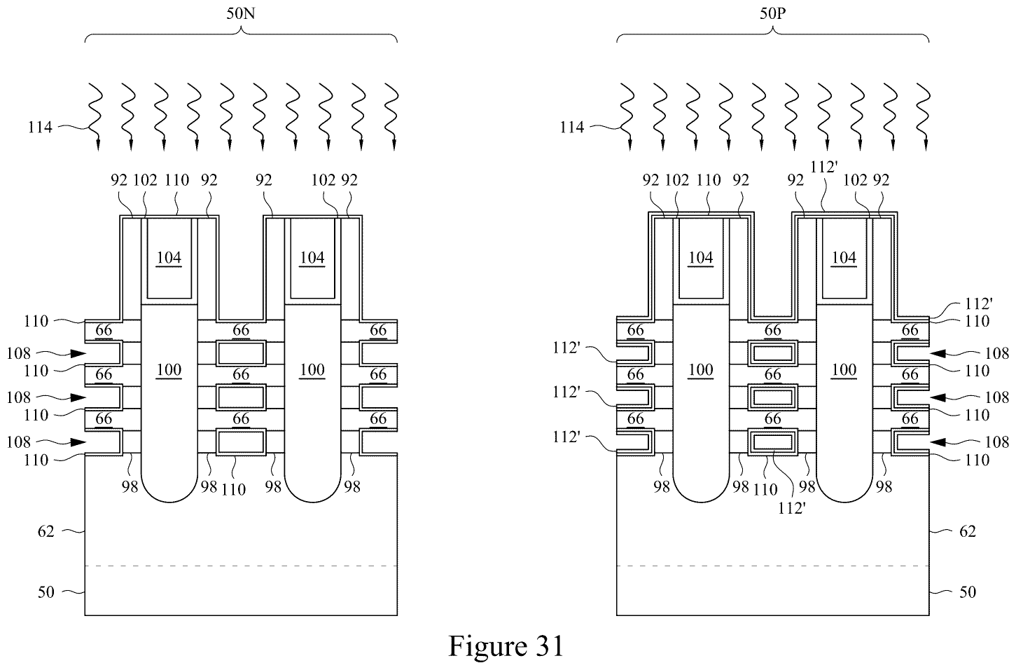

In FIG. 31, the mask 157 is removed and a silicon soak process 114 is performed, in accordance with some embodiments. The mask 157 may be removed using a suitable technique, such as an etch process, an ashing process, or the like. After removing the mask 157, the gate dielectrics 110 is exposed in the n-type region 50N and the first WF layer 112 is exposed in the p-type region 50P. The silicon soak process 114 may be similar to that described previously for FIGS. 18A-18C. For example, the silicon soak process 114 forms a silicon-containing layer (not separately illustrated) on the first WF layer 112 in the p-type region 50P. In some cases, the silicon soak process 114 may also form a silicon-containing layer (not separately illustrated) on the gate dielectrics 110 in the n-type region 50N. In some embodiments, any silicon-containing layer formed in the n-type region 50N is left remaining during subsequent processing. After performing the silicon soak process 114, the first WF layer 112 is referred to herein as the post-soak first WF layer 112′ or simply as the first WF layer 112′.

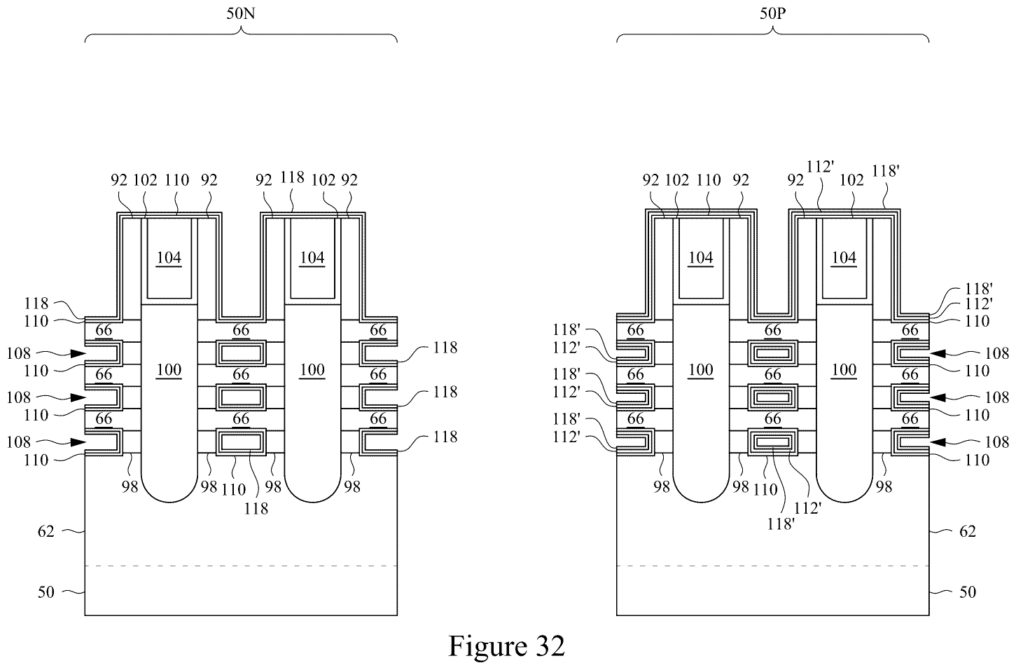

In FIG. 32, a second WF layer 118 is formed over the n-type region 50N and the p-type region 50P, in accordance with some embodiments. The second WF layer 118 is formed over the gate dielectrics 110 in the n-type region 50N and is formed over the first WF layer 112′ in the p-type region 50P. The second WF layer 118 may be similar to the second WF layer 118 described previously for FIGS. 23A-23C, and may be formed using similar techniques. For example, the second WF layer 118 may comprise aluminum. Similar to the previous discussion of the second WF layer 118, the silicon-containing layer of the first WF layer 112′ formed by the silicon soak process 114 inhibits the formation of the second WF layer 118 on the first WF layer 112′. Accordingly, the second WF layer 118 in the p-type region 50P may be formed having a smaller thickness, and is referred to as the second WF layer 118′.

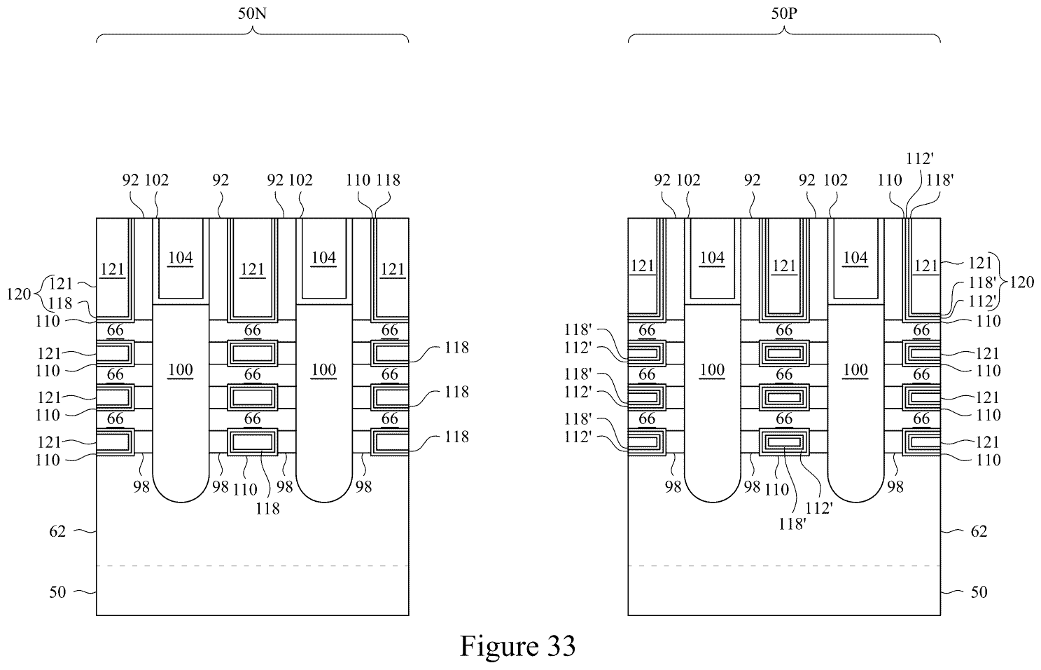

In FIG. 33, a fill material 121 is deposited over the second WF layer 118 to form gate electrodes 120, similar to the discussion of FIGS. 26A-26C. For example, the gate electrodes 120 of the n-type region 50N comprise the second WF layer 118 and the fill material 121, and the gate electrodes 120 of the p-type region 50P comprise the first WF layer 112′, the second WF layer 118′, and the fill material 121. The fill material 121 may be a similar to the fill material 121 described for FIGS. 26A-26C, and may be formed using similar techniques. In this manner, gate structures comprising gate dielectrics 110 and gate electrodes 120 may be formed. The structure may be subsequently processed using appropriate process steps, such as those described previously for FIGS. 27A-28C.

Embodiments may achieve advantages. Performing a silicon soak process on a p-type work function tuning layer modifies the surface of the p-type work function tuning layer such that the growth of an n-type work function on the surface is reduced. For example, the silicon soak process can form a silicon-containing layer on the p-type work function tuning layer that reduces the growth rate and thickness of the n-type work function tuning layer. The techniques described herein allow for a thinner n-type work function tuning layer to be formed on a p-type work function tuning layer. Forming a thinner n-type work function tuning layer in this manner can reduce the amount of material that undesirably diffuses from the n-type work function tuning layer into the p-type work function tuning layer. For example, the techniques described herein can reduce the diffusion of aluminum from the n-type work function tuning layer into the p-type work function tuning layer. Reducing the amount of aluminum that diffuses into the p-type work function tuning layer can reduce undesirable effects due to the presence of aluminum in the p-type work function tuning layer, such as increased threshold voltage or decreased flat-band voltage. In this manner, the use of a silicon soak process as described herein can improve device performance and improve device uniformity.

In an embodiment of the present disclosure, a method includes depositing a gate dielectric layer on a first channel region; depositing a p-type work function tuning layer on the gate dielectric layer; exposing the p-type work function tuning layer to a silicon-based precursor for a duration of time; and depositing a n-type work function tuning layer on the p-type work function tuning layer. In an embodiment, the silicon-based precursor includes at least one of silane, disilane, trisilane, tetrasilane, methylsilane, dimethylsilane, ethylsilane, methyldisilane, dimethyldisilane, hexamethyldisilane, or tris(dimethylamino)silane. In an embodiment, the p-type work function tuning layer includes titanium nitride. In an embodiment, the n-type work function tuning layer includes aluminum. In an embodiment, exposing the p-type work function tuning layer to the silicon-based precursor forms a silicon oxide layer on the p-type work function tuning layer. In an embodiment, the method includes depositing the gate dielectric layer on a second channel region; and exposing the gate dielectric layer on the second channel region to the silicon-based precursor for the duration of time. In an embodiment, exposing the p-type work function tuning layer to the silicon-based precursor includes a process temperature in the range of 0° C. to 900° C. In an embodiment, the duration of time is in the range of 1 second to 600 seconds.

In an embodiment of the present disclosure, a method includes forming a first gate dielectric layer on a first channel region and a second gate dielectric layer on a second channel region; forming a first work function tuning layer over the first gate dielectric layer and over the second gate dielectric layer; performing a surface modification process on the first work function tuning layer to form a silicon-containing layer on the first work function tuning layer; removing the first work function tuning layer from the first gate dielectric layer; and forming a second work function tuning layer on the first gate dielectric layer and over the first work function tuning layer that is over the second gate dielectric layer. In an embodiment, a thickness of the second work function tuning layer on the first gate dielectric layer is greater than a thickness of the second work function tuning layer over the first work function tuning layer. In an embodiment, a growth rate of forming the second work function tuning layer on the first gate dielectric layer is greater than a growth rate of forming the second work function tuning layer over the first work function tuning layer. In an embodiment, the forming of the second work function tuning layer includes an aluminum-based precursor and a titanium-based precursor. In an embodiment, the surface modification process includes exposing the first work function tuning layer to silane molecules or organosilane molecules. In an embodiment, the surface modification process replaces hydroxyl bonds with silicon-oxygen bonds. In an embodiment, the silicon-containing layer is a silicon oxide monolayer. In an embodiment, forming the second work function tuning layer over the first work function tuning layer includes forming aluminum-oxygen-silicon bonds.

In an embodiment of the present disclosure, a device includes a first gate structure over first nanostructures, wherein the first gate structure includes a first gate dielectric layer; a first layer of a n-type work function tuning material over the first gate dielectric layer; and a metal fill material over the first layer of the n-type work function tuning material; and a second gate structure over second nanostructures, wherein the second gate structure includes a second gate dielectric layer; a first layer of a p-type work function tuning material over the second gate dielectric layer; a first silicon-containing layer over the first layer of the p-type work function tuning material; a second layer of the n-type work function tuning material over the first silicon-containing layer; and the metal fill material over the second layer of the n-type work function tuning material. In an embodiment, a thickness of the first layer of the n-type work function tuning material is greater than a thickness of the second layer of the n-type work function tuning material. In an embodiment, the device includes a silicon-containing layer between the first gate dielectric layer and the first layer of the n-type work function tuning material. In an embodiment, the first silicon-containing layer includes at least one monolayer of silicon oxide.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
depositing a gate dielectric layer on a first channel region;
depositing a p-type work function tuning layer on the gate dielectric layer;
exposing the p-type work function tuning layer to a silicon-based precursor for a duration of time; and
depositing a n-type work function tuning layer on the p-type work function tuning layer.

2. The method of claim 1, wherein the silicon-based precursor comprises at least one of silane, disilane, trisilane, tetrasilane, methylsilane, dimethylsilane, ethylsilane, methyldisilane, dimethyldisilane, hexamethyldisilane, or tris(dimethylamino)silane.

3. The method of claim 1, wherein the p-type work function tuning layer comprises titanium nitride.

4. The method of claim 1, wherein the n-type work function tuning layer comprises aluminum.

5. The method of claim 1, wherein exposing the p-type work function tuning layer to the silicon-based precursor forms a silicon oxide layer on the p-type work function tuning layer.

6. The method of claim 1 further comprising:
depositing the gate dielectric layer on a second channel region; and
exposing the gate dielectric layer on the second channel region to the silicon-based precursor for the duration of time.

7. The method of claim 1, wherein exposing the p-type work function tuning layer to the silicon-based precursor comprises a process temperature in the range of 0° C. to 900° C.

8. The method of claim 1, wherein the duration of time is in the range of 1 second to 600 seconds.

9. A method comprising:
forming a first gate dielectric layer on a first channel region and a second gate dielectric layer on a second channel region;
forming a first work function tuning layer over the first gate dielectric layer and over the second gate dielectric layer;
performing a surface modification process on the first work function tuning layer to form a silicon-containing layer on the first work function tuning layer;
removing the first work function tuning layer from the first gate dielectric layer; and
forming a second work function tuning layer on the first gate dielectric layer and over the first work function tuning layer that is over the second gate dielectric layer.

10. The method of claim 9, wherein a thickness of the second work function tuning layer on the first gate dielectric layer is greater than a thickness of the second work function tuning layer over the first work function tuning layer.

11. The method of claim 9, wherein a growth rate of forming the second work function tuning layer on the first gate dielectric layer is greater than a growth rate of forming the second work function tuning layer over the first work function tuning layer.

12. The method of claim 9, wherein the forming of the second work function tuning layer comprises an aluminum-based precursor and a titanium-based precursor.

13. The method of claim 9, wherein the surface modification process comprises exposing the first work function tuning layer to silane molecules or organosilane molecules.

14. The method of claim 9, wherein the surface modification process replaces hydroxyl bonds with silicon-oxygen bonds.

15. The method of claim 9, wherein the silicon-containing layer is a silicon oxide monolayer.

16. The method of claim 9, wherein forming the second work function tuning layer over the first work function tuning layer comprises forming aluminum-oxygen-silicon bonds.

17. A device comprising:
a first gate structure over a first plurality of nanostructures, wherein the first gate structure comprises:
a first gate dielectric layer;
a first layer of a n-type work function tuning material over the first gate dielectric layer; and
a metal fill material over the first layer of the n-type work function tuning material; and
a second gate structure over a second plurality of nanostructures, wherein the second gate structure comprises:
a second gate dielectric layer;
a first layer of a p-type work function tuning material over the second gate dielectric layer;
a first silicon-containing layer over the first layer of the p-type work function tuning material;
a second layer of the n-type work function tuning material over the first silicon-containing layer; and
the metal fill material over the second layer of the n-type work function tuning material.

18. The device of claim 17, wherein a thickness of the first layer of the n-type work function tuning material is greater than a thickness of the second layer of the n-type work function tuning material.

19. The device of claim 17 further comprising a silicon-containing layer between the first gate dielectric layer and the first layer of the n-type work function tuning material.

20. The device of claim 17, wherein the first silicon-containing layer comprises at least one monolayer of silicon oxide.
